(19) United States
(12) Patent Application Publication
(10) Pub. No.: US 2016/0216369 A1
(43) Pub. Date: Jul. 28, 2016

(54) APPARATUS AND METHODS FOR CONTROLLING THE OUTPUT FREQUENCY OF A LASER

(71) Applicants: Anantharaman KUMARAKRISHNAN, Toronto (CA); Nima AFKHAMI-JEDDI, Richmond Hill (CA); Adam CAREW, Toronto (CA); Andrejs VOROZCOVS, Toronto (CA); Hermina BEICA, Woodbridge (CA)

(72) Inventors: Anantharaman KUMARAKRISHNAN, Toronto (CA); Nima AFKHAMI-JEDDI, Richmond Hill (CA); Adam CAREW, Toronto (CA); Andrejs VOROZCOVS, Toronto (CA); Hermina BEICA, Woodbridge (CA)

(21) Appl. No.: 15/024,510

(22) PCT Filed: Sep. 26, 2014
(86) PCT No.: PCT/CA2014/000715

§ 371 Date: Mar. 24, 2016

Related U.S. Application Data
(60) Provisional application No. 61/882,701, filed on Sep. 26, 2013.

(51) Int. Cl. G01S 7/484; H01S 5/14; H01S 3/139; H01S 5/0687

(52) U.S. Cl. CPC G01S 7/484; H01S 5/0687; H01S 5/143; H01S 3/1392

(57) ABSTRACT

Apparatus and method for controlling a frequency of laser light based on a reference medium are disclosed. An exemplary method comprises controlling the frequency based on a comparison of a measured spectrum of a physical property associated with the reference medium with a reference spectrum of the physical property to identify a set point for the measured physical property and an initial value for a control variable corresponding to the set point.

### TECHNICAL FIELD

The disclosure relates generally to frequency stabilization of laser light, and more particularly to apparatus and methods for controlling the frequency of laser light.

### BACKGROUND OF THE ART

Diode lasers are a versatile tool in atomic physics and spectroscopy research owing to their reliability, economy and compactness. Generally, a free-running diode laser can satisfy many applications. However, in other applications which require the frequency of the laser source to have a higher stability, such as optical communication, high resolution spectroscopy and gas remote sensing detection, a frequency-stabilized diode laser is usually required since thermal or mechanical perturbations can cause undesirable changes in the frequency and hence the wavelength of the output laser light.

Frequency stabilization can be accomplished by stabilizing the diode laser to an absolute frequency reference such as a gas absorption line. To stabilize the frequency of a diode laser, a wavelength modulation technique is often adopted. It can generate a derivative-like error signal of absorption as a function of wavelength. The linear region around the zero crossing is used as a feedback signal to dynamically drive the laser wavelength towards the zero crossing that corresponds to the absorption line center. The operation of locking the laser frequency onto an absorption line can be time consuming and frustrating. For example, since the zero crossing corresponding to the line center can be confused with the zero signal seen when the laser wavelength is far away from the line centre, the laser must first be manually tuned close to the line center within the locking range. Then the lock can be acquired by engaging the feedback loop. If unlocking occurs, these steps must be repeated.

Improvement is therefore desirable.

### SUMMARY

The disclosure describes components, apparatus and methods useful in controlling a frequency of laser light. In various embodiments, the components, apparatus and methods disclosed herein may be used to control the frequency of laser light based on a reference spectrum of a physical property associated with a reference medium where the reference spectrum comprises one or more frequency markers. In various embodiments, the control of the frequency of the laser light may be based on a comparison between the reference spectrum and a measured spectrum of the physical property associated with the reference medium and a determination whether at least a partial match exists between the reference spectrum and the measured spectrum. The components, apparatus and methods disclosed herein may be used in conjunction with frequency-tunable laser sources.

In one aspect, the disclosure describes a method for controlling a frequency of laser light based on a reference spectrum of a physical property associated with a reference medium where the reference spectrum comprises a selected frequency marker. The method may comprise:
directing at least some of the laser light output by a laser source toward the reference medium;
varying the frequency of the laser light by controllably varying a first control variable;
measuring the physical property associated with the reference medium while the at least some laser light is being directed toward the reference medium and while the first control variable is being varied to generate a measured spectrum of the physical property as a function of the first control variable;
comparing the measured spectrum with the reference spectrum to determine whether at least a partial match exists between the measured spectrum and the reference spectrum; and
conditioned upon the at least partial match existing:
   identifying a set point for the measured physical property corresponding to the selected frequency marker in the reference spectrum;
   identifying an initial value for the first control variable corresponding to the set point for the measured physical property; and
   controlling the frequency of the laser light based on the set point for the measured physical property and the initial value for the first control variable.

In another aspect, the disclosure describes an apparatus for controlling a frequency of laser light based on a reference spectrum of a physical property associated with a reference medium where the reference spectrum comprises a selected frequency marker. The apparatus may comprise:
at least one processor;
at least one storage medium including machine-readable instructions executable by the at least one processor and configured to cause the at least one processors to:
   generate one or more signals for causing the frequency of the laser light to be varied by controllably varying a first control variable while at least some of the laser light output by a laser source is directed toward the reference medium;
   using data representative of measurements of the physical property associated with the reference medium taken while the at least some laser light is being directed toward the reference medium and while the first control variable is being varied, generating data representative of a measured spectrum of the physical property as a function of the first control variable;
   compare the data representative of the measured spectrum with data representative of the reference spectrum to determine whether at least a partial match exists between the measured spectrum and the reference spectrum; and
   conditioned upon the at least partial match existing:
      generating data representative of a set point for the measured physical property corresponding to the selected frequency marker in the reference spectrum;
      generating data representative of an initial value for the first control variable corresponding to the set point for the measured physical property; and
      generating one or more signals for controlling the frequency of the laser light based on the set point for the measured physical property and the initial value for the first control variable.

In another aspect, the disclosure describes laser systems comprising apparatus (controllers) for controlling the frequency of laser light.

In another aspect, the disclosure describes gravity meters comprising apparatus (controllers) for controlling the frequency of laser light.

In another aspect, the disclosure describes laser interferometry detection and ranging (lidar) transmitters comprising apparatus (controllers) for controlling the frequency of laser light.

Further details of these and other aspects of the subject matter of this application will be apparent from the detailed description and drawings included below.

### DESCRIPTION OF THE DRAWINGS

Reference is now made to the accompanying drawings, in which:

FIG. 1 shows a schematic representation of a laser system in accordance with the present disclosure;

FIG. 2 shows a schematic representation of an exemplary embodiment the laser system of FIG. 1;

FIG. 3 shows a schematic representation of another exemplary embodiment of the laser system of FIG. 1;

FIG. 4 shows a schematic representation of another exemplary embodiment of the laser system of FIG. 1;

FIG. 5 shows a schematic representation of a vapor cell for use as a reference medium in the laser system of FIG. 1;

FIG. 6 shows a schematic representation of a method in accordance with the present disclosure;

FIGS. 7A-7C collectively show a screen shot of an exemplary graphic user interface associated with the operation of a laser system;

FIG. 8 shows a schematic representation of measured and reference spectra of a physical property associated with a reference medium used in controlling the frequency of laser light;

FIGS. 9A and 9B show exemplary plots illustrating stability in the frequency of laser light during control using a rubidium vapor cell as a reference medium;

FIG. 10 shows a schematic representation of a gravity meter comprising a laser system in accordance with the present disclosure;

FIGS. 11A and 11B respectively show a plot of gravity measurements using a gravity meter comprising a commercial iodine-stabilized helium-neon laser and a plot showing characteristic fit residuals for a single drop of a proof mass;

FIGS. 12A and 12B respectively show a plot of gravity measurements using a gravity meter comprising a laser according to the present disclosure and a plot showing characteristic fit residuals for a single drop of a proof mass;

FIG. 13 shows a schematic representation of a transmitter for a lidar device comprising a laser system in accordance with the present disclosure;

FIG. 14 is a schematic illustration of a reference medium of the laser system comprising a fiber Bragg grating (FBG);

FIG. 15 is a plot showing two FBG notches (peaks) that have been temperature tuned to the vicinity of a reference spectrum associated with rubidium 87;

FIG. 16 is a larger magnification plot showing the larger FBG notch in relation to reference spectrum of FIG. 15;

FIG. 17 is a plot of notch frequency for an exemplary FBG versus temperature;

FIG. 18 is a plot showing the first derivative and the third derivative of a measured spectrum obtained from an iodine vapor cell;

FIGS. 19A and 19B show exemplary plots illustrating stability in the frequency of laser light during control using an iodine vapor cell as a reference medium;

FIG. 20A shows a rubidium saturated absorption set-up for monitoring the scan range and long-term performance of an exemplary laser system; and

FIG. 20B shows a representative beat note spectrum obtained using the set-up of FIG. 20A;

FIG. 21 is an image of a part of an exemplary laser system in accordance with that shown in FIG. 3;

FIG. 22 is an image of an exemplary enclosure of a laser system;

FIG. 23 is an image of an exemplary controller of a laser system; and

FIGS. 24A-24H collectively show a screen shot of another exemplary graphic user interface associated with the operation of a laser system.

### DETAILED DESCRIPTION

Aspects of various embodiments are described through reference to the drawings.

The present disclosure describes, components, apparatus and methods useful in controlling the operation (e.g., frequency) of a laser system. The disclosure is meant to be exemplary only, and one skilled in the relevant arts will recognize that changes may be made to the various embodiments described herein without departing from the scope of the invention disclosed. Even though the components, apparatus and methods disclosed herein may be said to stabilize (e.g., lock) the frequency of the laser light output by a laser source, it should be understood that the stabilization provided may not be absolute stabilization. It should also be understood that the levels of stabilization may vary between embodiments disclosed herein and that different levels of stabilization may be suitable for different applications.

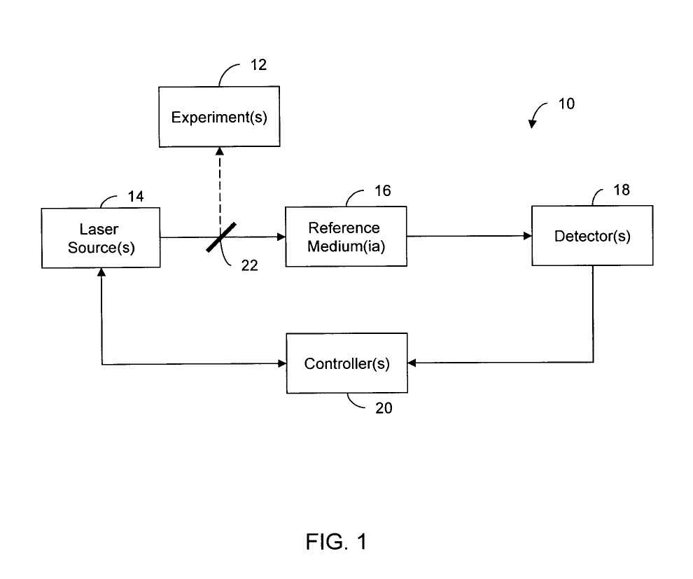

FIG. 1 shows a schematic representation of a laser system, generally shown at 10, in accordance with the present disclosure. As described below, laser system 10 may comprise components and apparatus for controlling the frequency and hence the wavelength of the laser light output by laser system 10. Accordingly, in various embodiments, laser system 10 may be configured to output frequency-stabilized laser light. Laser system 10 may be configured to output laser light to experiment(s) 12 (referenced hereinafter as “experiment 12”). Experiment 12 may comprise any suitable application for which frequency-stabilized and/or other laser light may be required. Experiment 12 may comprise applications related to atomic physics, metrology and telecommunication. For example, laser system 10 may be used as a tool in spectroscopy, atom/ion trapping and cooling, Bose-Einstein condensate applications, interferometry, Raman spectroscopy and microscopy as well as other applications.

In various embodiments, laser system 10 may have a relatively narrow spectral line width. Accordingly, laser system 10 may be used in atomic physics labs for research and metrology. Laser system 10 may be particularly well-suited for applications that require the laser frequency to be actively stabilized. In various embodiments, laser system 10 may be configured to be actively stabilized with little to no human intervention (e.g., automatically) once laser system 10 has been is set up and is running.

Laser system 10 may also be used in gravity measurement applications and, as described further below, may be integrated in a falling corner cube absolute gravity meter. Laser system 10 may also be used as a relatively stable source (i.e., seed laser) for high power lasers used in research and industry for applications including lidar and may be integrated in such systems.

Laser system 10 may comprise one or more laser sources 14 (referenced hereinafter as “laser source 14”), one or more reference media 16 (referenced hereinafter as “reference medium 16”), one or more detectors 18 (referenced hereinafter as “detector 18”) and one or more controllers 20 (e.g., apparatus) (referenced hereinafter as “controller 20”). Controller 20 may be configured to control (e.g., stabilize) the frequency of laser light output by laser source 14. Control of the frequency may be conducted in a closed-loop manner according to known proportional, integral and/or derivative (e.g., PID or any combinations of proportional, integral and derivative control) or other suitable feedback or feed-forward control methods. Laser source 14 may comprise any suitable frequency-tunable laser source(s). For example, laser source 14 may comprise one or more semiconductor laser devices which may be electrically pumped such as one or more laser diodes.

Reference medium 16 may comprise any suitable medium that may be used as a basis for stabilizing the frequency of the laser light output by laser source 14. For example, the control of the frequency of the laser light may be based on a physical property associated with reference medium 16 that is measured when the laser light is directed toward reference medium 16 and interacts with reference medium 16. As explained further below, reference medium 16 may comprise, for example, one or more vapor cells (e.g., rubidium, cesium, iodine, etc.), one or more interference filters and/or one or more fiber Bragg gratings (FBGs). Detector 18 may be configured to detect a physical property associated with reference medium 16 in response to laser light from laser source 14 being directed toward reference medium 16 and interacting with reference medium 16. For example, detector 18 may comprise any suitable photo detectors configured to detect an intensity of the laser light either passing through a vapor cell or being reflected by an interference filter or an FBG. In various embodiments, detector 18 may include one or more photo diodes. Detector 18 may be selected to be responsive to laser light within the operating frequency/wavelength range of laser source 14. In some embodiments, depending on the wavelength/frequency of output light, detector 18 may be optically coupled to receive light from laser diode 20 via a fiber optic cable. In some embodiments, detector 18 may comprise a spectrometer.

Controller 20 may be configured to receive signals from detector 18 and generate one or more signals for controlling the operation of laser source 14. For example, controller 20 may be configured to vary/adjust one or more control variables (e.g., length of an external cavity of a laser diode, drive current to a laser diode and/or temperature of a laser diode) associated with the operation of laser source 14 in order to maintain laser source 14 at or relatively near a desired set point. For example, the set point may comprise a magnitude of the physical property detected by detector 18. In various embodiments, the set point may comprise a predefined intensity of laser light detected by detector 18 (e.g., photo diodes). Reference medium 16 may be selected based on one or more of its physical properties and also a laser light frequency desired from laser source 14. For example, a selected vapor cell may exhibit one or more absorption peaks (and corresponding light intensity values detectable via detector 18) which controller 20 may use as one or more set points during control of laser source 14. Alternatively or in addition, a selected interference filter or FBG may exhibit one or more reflection peaks (and corresponding light intensity values detectable via detector 18) which controller 20 may use as one or more set points during control of laser source 14. In various embodiments, such absorption/reflection peaks or other characteristics of the measured physical property may correspond to a frequency/wavelength of laser light to which laser source 14 may be locked onto. In various embodiments, such frequency marker may correspond to an atomic or molecular transition associated with reference medium 16.

Laser system 10 may also comprise one or more beam splitters 22 (referenced hereinafter as “beam splitter 22”). Beam splitter 22 may be disposed in the optical path between laser source 14 and reference medium 16 so that laser light output from laser source 14 may be directed toward experiment 12 and at least a portion of laser light may be directed toward reference medium 16 for the purpose of controlling the frequency of the laser light.

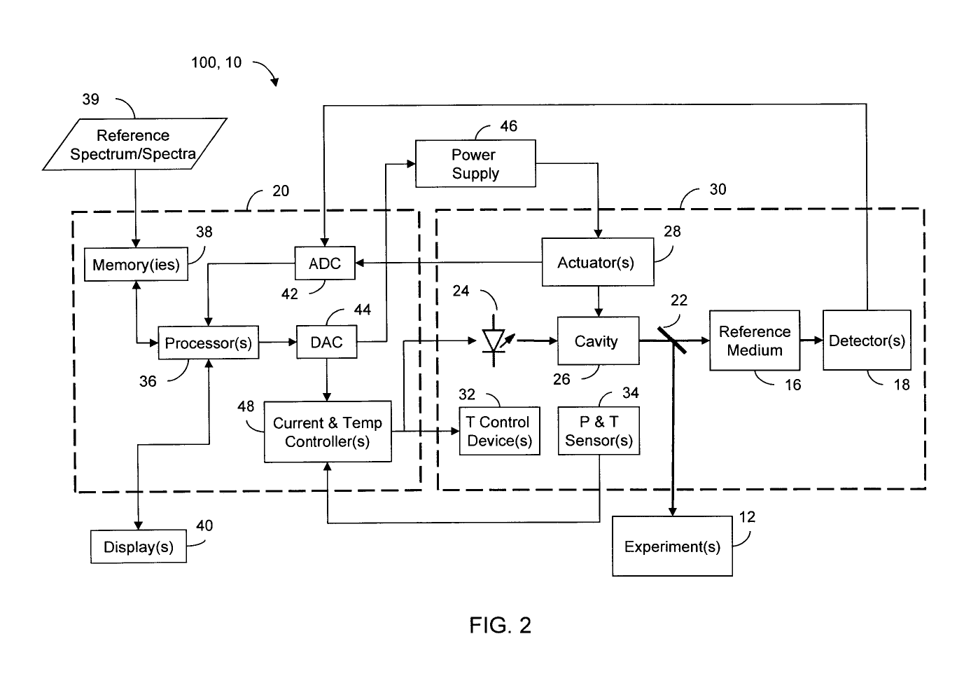

FIG. 2 shows a schematic representation of an exemplary embodiment laser system 10 shown in FIG. 1 where like elements are referenced using like reference numerals. The laser system shown in FIG. 2 is generally shown at 100. As mentioned above, laser system 100 may comprise laser diode 24 and an adjustable (e.g., variable length) laser cavity 26 associated (e.g., in optical communication) with laser diode 24. Accordingly, laser source 14 may comprise laser diode 24 and laser cavity 26, which may be external to laser diode 24. Laser system 100 may also comprise one or more suitable actuators 28 (referenced hereinafter as “actuator 28”) for adjusting/varying a length of laser cavity 26 for the purpose of adjusting/varying the frequency of the laser light. In various embodiments, actuator 28 may comprise one or more piezoelectric transducers but it should be understood that other suitable types of actuators or means for varying the length of laser cavity 26 could also be used. Laser diode 24 and laser cavity 26 may be considered a conventional or other type of external cavity diode laser (ECDL). However, it should be understood that other types of frequency-tunable laser sources could be used in conjunction with the components, apparatus and methods disclosed herein.

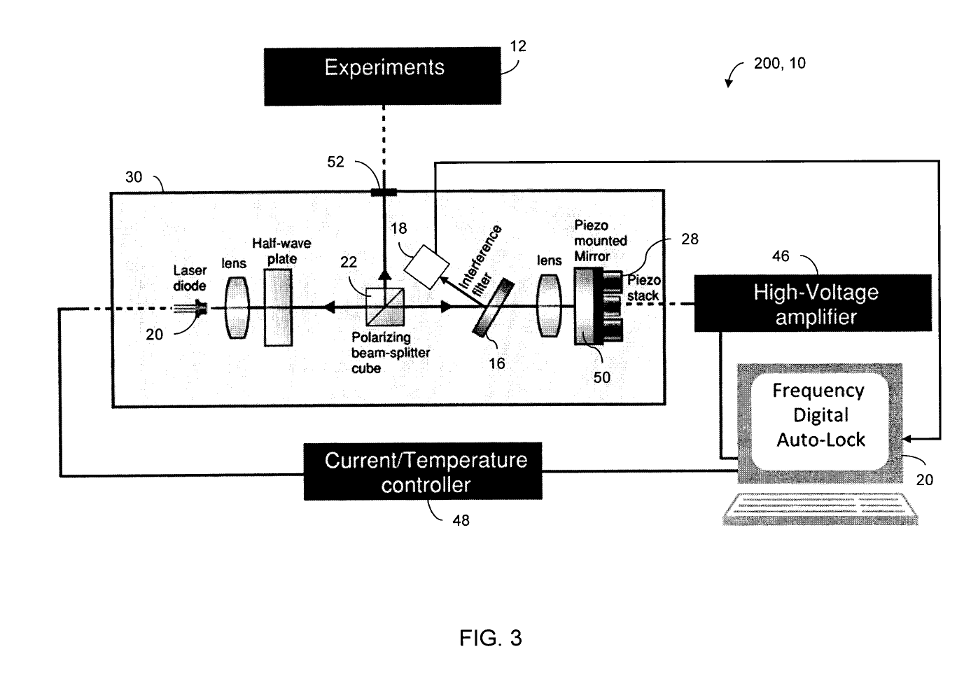

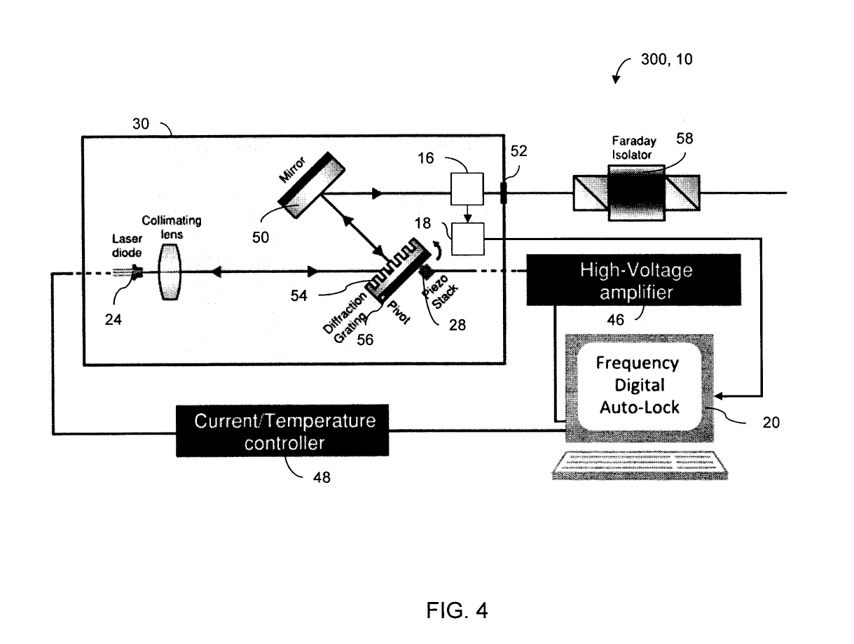

Laser diode 24 may be disposed inside enclosure 30 and the laser light may be directed toward experiment 12 via a suitable window (e.g., see element 52 in FIGS. 3 and 4) permitting the passage of at least some of the laser light through enclosure 28. One or more additional components may optionally also be disposed inside enclosure 30. For example, one or more of laser cavity 26, actuator 28, reference medium 16 and detector 18 may also be disposed inside enclosure 30. Enclosure 30 may be configured to permit the environmental conditions inside of enclosure to be monitored and/or controlled. For example, enclosure 30 may be, at least to some extent, substantially pressure sealed and/or moisture sealed. In various embodiments, enclosure 30 may also comprise some thermal insulating properties so that some thermal gradient between the inside of enclosure 30 and the environment outside of enclosure 30 may be maintained during operation.

Laser system 100 may comprise one or more temperature control devices 32, which may be used to control the temperature inside of enclosure 30. Temperature control device 32 may be configured to controllably add and/or remove heat from the inside of enclosure 30 based on a desired temperature to be maintained inside of enclosure 30. In various embodiments, temperature control device 32 may comprise a suitable thermoelectric heating and/or cooling device using the Peltier effect to create a heat flux between the junction of two different types of materials. One or more sensors 34 may be disposed inside of enclosure 30 or otherwise positioned to monitor one or more environmental properties inside of enclosure 30. In various embodiments, sensors 34 may comprise conventional or other types of suitable temperature, pressure and/or humidity sensors. For example, enclosure 30 may be substantially hermetically sealed using one or more suitable sealing members. In some embodiments, interfaces (e.g., feedthroughs) to enclosure 30 may be substantially sealed using rubber O-rings for example. Accordingly, enclosure 30 may be pressurized or evacuated using a vacuum pump (not shown) and subsequently “valved-off” so that the pressure/vacuum condition inside of enclosure 30 may be substantially maintained during operation of laser system 10, 100.

Controller 20 may, for example, comprise one or more digital computers or other data processors and related accessories that control at least some aspects of the performance of laser system 10, 100. In various embodiments, controller 20 may comprise one or more processors 36 (referred hereinafter as “processor 36”), which may be configured for digital data processing. For example, processor 36 may include one or more microcontrollers or other suitably programmed or programmable logic circuits.

Controller 20 may also comprise memory(ies) 38 (referred hereinafter as “memory 38”) including memory data devices or register(s). Memory 38 may comprise any data storage device(s) suitable for storing data received and/or generated by processor 36, preferably retrievably. For example, memory 38 may comprise one or more of any or all of erasable programmable read only memory(ies) (EPROM), flash memory(ies) or other electromagnetic media suitable for storing electronic data signals in volatile or non-volatile, non-transient form. Memory 38 may comprise any storage means (e.g. device(s)) suitable for retrievably storing machine-readable instructions executable by processor 36. Such machine-readable instructions may be incorporated into one or more suitable computer programming products. Such machine-readable instructions may cause processor 36 to generate one or more signals useful in controlling at least some aspect (e.g., frequency of laser light) of laser system 100 based on data associated with the operation of laser system 100. Memory 38 may also be used to store data representative of one or more reference spectra 39 (referred hereinafter as “reference spectrum 39”) of one or more physical properties associated with reference medium 16. As explained further below, reference spectrum 39 may be used to lock the frequency of laser light to a frequency marker associated with reference medium 16. Machine-readable instructions may be configured to cause controller 20 to carry out methods based on one or more algorithms. For example such instructions may permit the same controller 20 to be used in different systems 10 using different types of reference media 16 and for outputting light at different wavelengths (e.g., 780 nm or 633 nm).

One or more displays 40 (referred hereinafter as “display 40”) may provide an interface for a user to interact with and control at least some aspect of the operation of controller 20 and laser system 100. In various embodiments, display 40 may comprise a touch screen configured to receive input from a user via a suitable graphic user interface. Alternatively or in addition, other one or more user-input devices (not shown) such as mice, touchpads, keyboards and trackballs may also be provided to permit a user to interact and control the operation of controller 20 and laser system 100. For example, the one or more user-input devices may permit a user to input data (e.g., set points, control parameters) that may be used by controller 20 during operation of controller 20. Display 40 may also present data to a user regarding the operation and/or status of laser system 100.

Controller 20 may be configured to control the operation of laser system 100 by controlling one or more control variables based on one or more feedback signals. For example, controller 20 may be configured to control the operation of actuator 28 in order to controllably vary the length of laser cavity 26 (e.g., first control variable) and consequently vary the frequency of the laser light. In various embodiments, the length of laser cavity 26 may be varied to provide relatively fine tuning of the frequency of the laser light. The control of actuator 28 may be conducted based on one or more feedback signals received from detector 18 and optionally also based on one of more feedback signals received from actuator 28 so that the actual position of actuator 28 may be monitored and also used in the control loop. Accordingly, processor 36 may be configured to receive signals representative of the measured physical property associated with reference medium 16 from detector 18 via analog to digital converter 42 when at least some of the laser light is directed toward reference medium 16. The feedback signals from actuator 28 may be representative of a position of actuator 28 and may be received by processor 36 via analog to digital converter 42. The signals representative of the measured physical property associated with reference medium 16 and the signals representative of the position of actuator 28 may be received via separate channels of analog to digital converter 42. Based on the signals received from detector 18, actuator 28 and/or other sources, processor 36 may, based on suitable machine-readable instructions stored in memory 38, be caused to generate one or more control signals useful in controlling actuator 28. The control signals may be transmitted to actuator 28 via digital to analog converter 44 and power supply 46.

Controller 20 may also be configured to control a drive current to laser diode 24 (e.g., second control variable). The control of the drive current may provide fine and/or coarse control/tuning of the frequency of the laser light. For example, the drive current to laser diode 24 may permit the frequency of the laser light to be varied over a wide range of frequencies within the operating range of frequencies of laser diode 24 and the variation of the length of laser cavity 26 may permit the frequency of the laser light to be varied over a narrower range of frequencies within the operating range of frequencies of laser diode 24. Accordingly, depending on the magnitude of the error between the actual frequency of the laser light and the desired frequency of the laser light, it may be necessary in various embodiments that the drive current and optionally also the length of laser cavity 26 be adjusted in order to achieve the desired level of correction of the frequency of the laser light. For example, the drive current to laser diode 24 (and optionally the length of laser cavity 26) may be adjusted when a relatively large correction is required and only the length of laser cavity 26 may be adjusted when a relatively small correction is required. In various embodiments, different combinations of drive current and cavity length variations may be used to achieve the desired level of correction in the frequency of the laser light.

The function of controlling the drive current to laser diode 24 may be performed by processors 36 entirely or in combination with other digital and/or analog processor(s) and/or controller(s) part of controller 20. For example, in various embodiments, analog controller 48 (e.g., processor) may be used to control the drive current to laser diode 24. Accordingly, analog controller 48 may be configured to receive input from processor 36 via digital to analog converter 44 and output one or more signals useful in controlling the drive current to laser diode 24. For example processor 36 may provide instructions (e.g., set point) to analog controller 48 so that analog controller 48 may then control the drive current according to those instructions.

Controller 20 may be configured to also control a temperature inside of enclosure 30 (e.g., third control variable). Variations of the temperature of laser diode 24, cavity 26 and/or reference medium 26 may also cause variations in the frequency of the output laser light. The control of the temperature may provide fine and/or coarse control/tuning of the frequency of the laser light. In various embodiments, the temperature of enclosure 30 may or may not be used to provide active control of the frequency of the laser light. For example, the temperature of enclosure 30 may be controlled so that it is substantially maintained at a desired temperature. Accordingly, the control of the temperature inside of enclosure 30 may provide some protection against changes in temperature of the environment outside of enclosure 30 and may contribute to the overall stability of laser system 100. However, in various embodiments, it may be desirable to also vary/adjust the temperature inside of enclosure 30 to achieve a desired set point for the frequency of the laser light. Accordingly, depending on the magnitude of the error between the actual frequency of the laser light and the desired frequency of the laser light, it may be necessary in various embodiments to adjust the temperature, the drive current and optionally also the length of laser cavity 26 in order to achieve the desired level of correction of the frequency of the laser light. In various embodiments, different combinations of temperature adjustment, drive current adjustment and cavity length adjustment may be used to achieve the desired level of correction in the frequency of the laser light. Such adjustments may be controlled by controller 20 based on suitable machine-readable instructions stored in memory 38 and may be conducted substantially automatically with little to no user intervention.

The function of controlling the temperature inside enclosure 30 may be performed by processors 36 entirely or in combination with other digital and/or analog processor(s) and/or controller(s) part of controller 20. For example, in various embodiments, analog controller 48 may also be used to control the temperature inside enclosure 30. Accordingly, analog controller 48 may be configured to receive input (e.g., set point) from processor 36 via digital to analog converter 44 and output one or more signals useful in controlling the operation of temperature control device 32. For example processor 36 may provide instructions to analog controller 48 so that analog controller 48 may then control the operation of temperature control device 32 according to those instructions. Analog controller 48 may also receive feedback from temperature sensor 34 for the purpose of controlling the temperature inside of enclosure 30 in a closed loop manner. In various embodiments, feedback of temperature, pressure and/or humidity may also be provided to processor 36 via analog controller 48 or other means (not shown).

As mentioned above, enclosure 30 may be substantially pressure-sealed. The pressure sealing of enclosure 30 may provide at least some protection against variations in atmospheric pressure around laser system 100. Accordingly, the pressure sealing may contribute to the overall stability of laser system 100 in some embodiments/applications where laser system 100 may be exposed to changes in atmospheric pressure, altitude and/or humidity.

Controller 20 may be configured, via suitable machine-readable instructions stored on memory 38, to monitor the pressure inside of enclosure 30 via pressure sensor 34. In the event of a change in the pressure inside of enclosure 30, controller 20 may be configured to carry out some corrective action to compensate for the change in pressure. For example, controller 20 may be configured to compensate for the change in pressure (e.g., using calibration data stored in memory 38) by adjusting one or more control variables associated with the operation of laser system 100. Alternatively or in addition, depending on the magnitude of the pressure change inside of enclosure 30, controller 20 may be configured to output one or more messages to be displayed on display 40 to alert a user of laser system 100 that the pressure sealing of enclosure 30 may have failed.

The function of monitoring the pressure inside enclosure 30 may be performed by processors 36 entirely or in combination with other digital and/or analog processor(s) and/or controller(s) part of controller 20. For example, in various embodiments, analog controller 48 may also be used to monitor the pressure inside enclosure 30. Accordingly, analog controller 48 may receive feedback from pressure sensor 34.

FIG. 3 shows a schematic representation of another exemplary embodiment of laser system 10 shown in FIG. 1 where like elements are referenced using like reference numerals. The laser system of FIG. 3 is shown generally at 200. As mentioned above, different types of reference media 16 may be used in conjunction with the components, apparatus and methods disclosed herein. For example, laser system 200 shows an interference filter being used as reference medium 16 and detector 18 being configured to detect the intensity of the laser light reflected from the interference filter and provide feedback signals to controller 20. Laser system 200 may also comprise one or more piezoelectric transducers (e.g., piezo stack) used as actuator 28 for controllably moving mirror 50 to consequently controllably vary the length of laser cavity 26 (see FIG. 2) defined between laser diode 24 and mirror 50 in order to vary the frequency of the laser light. As mentioned above, laser light may be directed to experiment(s) 12 via window 52 defined or incorporated into enclosure 30. Window 52 may be at least partially transparent to the laser light while permitting the pressure sealing of enclosure 30 to be substantially maintained.

Tuning (including coarse tuning) of the interference filter of FIG. 3 may be achieved by tilting the interference filter. Tilting of the interference filter may be achieved by a suitable actuator (not shown) either disposed inside or outside of enclosure. For example, such actuator may be disposed outside and operationally coupled to the interference filter using a suitable gear train (e.g., 90-degree gear train) via a suitable feedthrough that may be configured to substantially maintain the hermetic sealed of enclosure 30. For example, this may permit the interference filter to be tuned while the (e.g., vacuum) condition(s) inside of enclosure 30 may be substantially maintained.

FIG. 4 shows a schematic representation of a further exemplary embodiment of laser system 10 shown in FIG. 1 where like elements are referenced using like reference numerals. The laser system of FIG. 4 is shown generally at 300 and may have a Littrow configuration. Accordingly, laser system 300 may comprise diffraction grating 54 rotatably coupled about pivot 56. Actuator 28 of laser system 300 may comprise one or more piezoelectric transducers configured to controllably cause rotation of diffraction grating 54 to thereby controllably vary the length of laser cavity 26 (see FIG. 2) defined between laser diode 24 and mirror 50 in order to vary the frequency of the laser light. Laser system 300 may further comprise Faraday isolator 58 or some other means to prevent unwanted feedback of output laser light into laser cavity 26.

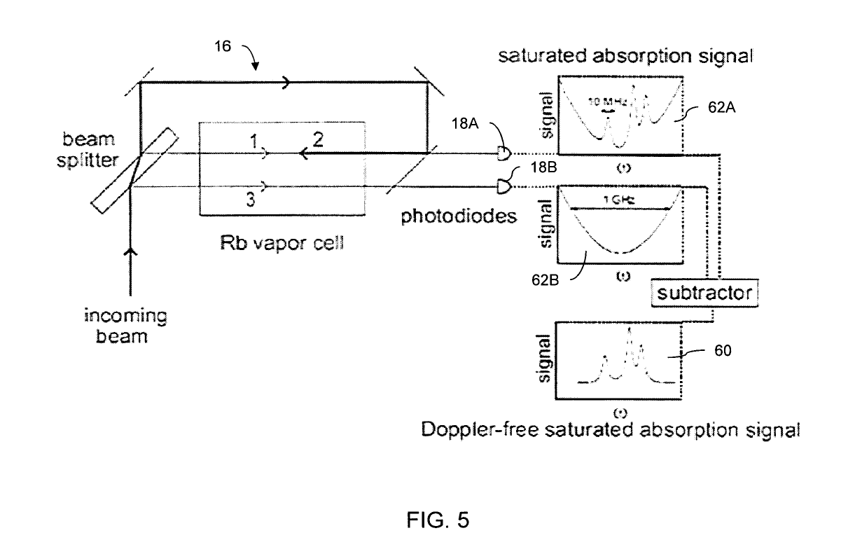

FIG. 5 shows a schematic representation of an exemplary vapor cell, which may be used as reference medium 16 in laser system 10. Vapor cell 16 may be magnetically shielded. In various embodiments, vapor cell 16 and detector 18 may be configured to produce substantially Doppler-free intensity values that can be fed back to controller 20. For example, when the frequency of the laser light is varied by the variation of one or more control variables of laser system 10 for example, and the intensity values are recorded, a substantially Doppler-free spectrum of measured intensities (e.g., measured spectrum 60) of laser light passing through vapor cell 16 may be recorded and stored in memory 38 for future analysis or computations by controller 20. Some techniques for producing Doppler-free spectroscopy are known and it should be understood that any suitable technique(s) may be used in conjunction with the apparatus and methods described herein. One such technique is illustrated in FIG. 5 and involves irradiating vapor cell 16 with overlapping, counter-propagating laser beams 1, 2. Each of the counter-propagating beams experiences an opposite Doppler shift as the other thereby substantially cancelling out the Doppler broadening effect.

In order to produce measured spectrum 60: first signal(s) 62A may be obtained via photo diode 18A to measure the output of vapor cell 16 from the two counter-propagating laser beams 1 and 2; second signal(s) 62B may be obtained via photo diode 18B to measure the output of vapor cell 16 from laser beam 3; and second signal(s) 62B may be subtracted from first signal(s) 62A to obtain measured spectrum 60, which may be substantially free of Doppler broadening effect.

During operation, laser systems 10, 100, 200, 300 may be used to output substantially frequency-stabilized (e.g., locked) laser light in based on reference medium 16. For example, the laser light may be frequency-stabilized based on reference spectrum 39 of at least one physical property associated with reference medium 16 where reference spectrum 39 may comprise at least one feature of interest, such as an atomic or molecular transition, which may be used as a frequency marker. The feature of interest may, for example, comprise an absorption peak associated with a vapor cell or a reflection peak associated with an interference filter or an FBG. In various embodiments, the stabilization of the laser light may be achieved via the adjustment of one or more control variables which may include, for example, a length of laser cavity 26, a drive current to laser diode 24 and the temperature of the laser diode 24 and/or any other component(s) housed in enclosure 30. As explained, further below, the use of a plurality of control variables in combination with the use of reference spectrum 39 and measured spectrum 60 for the purpose of controlling the frequency of the laser light may permit the frequency of the laser light to be brought back to or near the desired frequency even when the error between the actual frequency and the desired frequency is relatively large and may have been caused by a perturbation. In various embodiments, controller 20 may be configured to correct such large frequency errors substantially automatically with little or no involvement by a user.

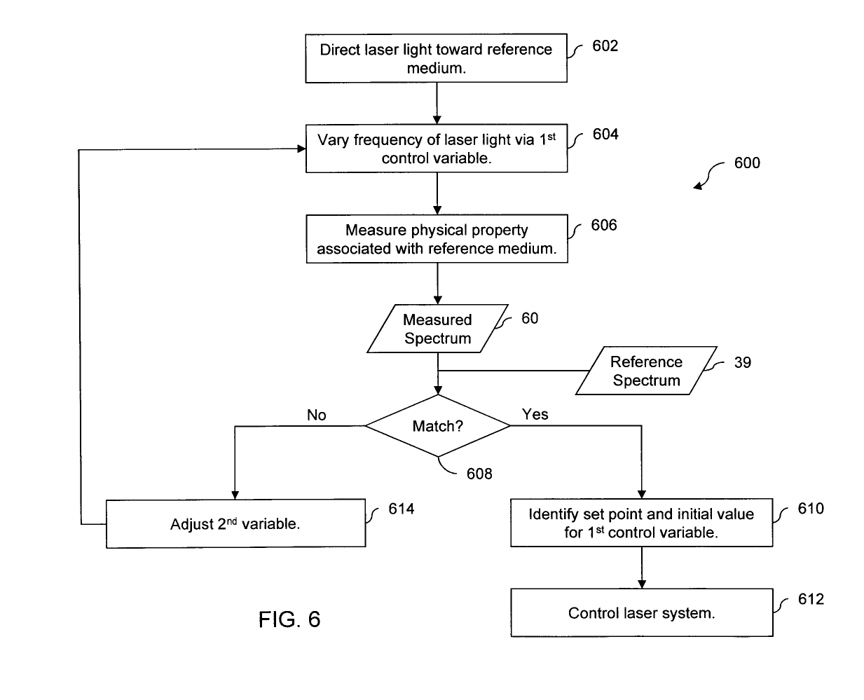

FIG. 6 shows a schematic representation of an exemplary method, generally shown at 600, in accordance with the present disclosure. Method 600 may be used for controlling a frequency of laser light based on reference spectrum 39 of a physical property associated with reference medium 16 where reference spectrum 39 comprises a selected frequency marker. Method 600 may be carried out substantially automatically or semi-automatically using any one of laser systems 10, 100, 200, 300. Some or all of method 600 and/or other operations disclosed herein may be carried out using controller 20 based on machine-readable instructions stored, for example, in memory 38. It should be understood that variations to the blocks and/or operations of method 600 may be made without departing from the teachings of the present disclosure. For instance, the blocks may be performed in a differing order, or blocks may be added, deleted, or modified.

Method 600 may comprise: directing at least some of the laser light output by laser source 14 toward reference medium 16 (see block 602); varying the frequency of the laser light by controllably varying a first control variable (see block 604); measuring the physical property associated with reference medium 16 while the at least some laser light is being directed toward reference medium 16 and while the first control variable is being varied to generate measured spectrum 60 of the physical property as a function of the first control variable (see block 606); and comparing measured spectrum 60 with reference spectrum 39 to determine whether at least a partial match exists between measured spectrum 60 and reference spectrum 39 (see block 608). Conditioned upon the at least partial match existing, method 600 may further comprise: identifying a set point for the measured physical property corresponding to the selected frequency marker in reference spectrum 16 (see block 610); identifying an initial value for the first control variable corresponding to the set point for the measured physical property (see block 610); and controlling the frequency of the laser light based on the set point for the measured physical property and the initial value for the first control variable (see block 612). The control of the frequency of the laser light may be conducted in a closed loop manner.

Depending on how far the actual frequency of the laser light may be relative to the desired frequency, one or more additional control variables may need to be adjusted to bring the frequency of the laser light closer to the desired frequency. For example, as explained above, control variables may include the length of laser cavity 26, the drive current to laser diode 24 and the temperature inside of enclosure 30. Accordingly, different control variables may be used to provide coarse and/or fine tuning of the frequency of the laser light. For example, the temperature inside of enclosure 30 and the drive current to laser diode 24 may be used for relatively coarse tuning by setting the frequency range over which laser diode 24 will operate. Within this range, the laser frequency of the laser light may be continuously, stepwise or otherwise scanned using actuator 28 to vary the length of laser cavity 26. Once the range has been set via the temperature and the drive current, further fine tuning of the laser frequency may be achieved via actuator 28. Depending on the severity of the perturbation which may have caused the frequency of the laser light to change and also the magnitude of the error between the actual frequency and the desired frequency, causing the frequency to return closer to the desired frequency may require one or more iterations of coarse and/or fine tuning via a plurality of control variables associated with the operation of laser system 10, 100, 200, 300. Controller 20 may be configured to automatically control such iterations based on suitable machine-readable instructions stored in memory 38.

In various embodiments, the determination whether a match exists between measured spectrum 60 and reference spectrum 39 may permit laser system 10 to be tuned to the correct frequency marker in reference spectrum 39. For example, even though reference spectrum 39 may contain a plurality of potential frequency markers, the identification of the desired frequency marker may be stored in memory 38 and the pattern matching methods disclosed herein may permit locking the frequency of the laser light to the correct frequency marker in reference spectrum 39 without mistakenly locking onto an incorrect frequency marker (e.g., locking to an incorrect absorption peak due to mode hopping). The pattern matching methods disclosed herein may also permit a relatively large reference spectrum 39 or portions thereof to be considered during the determination whether a match exists.

Depending on the magnitude of the error, method 600 may comprise adjusting a second control variable prior to varying the frequency of the laser light via the first control variable. Here, the second variable may provide relatively coarse tuning and the first variable may provide relatively fine tuning. The adjustment of the second control variable may be conducted prior to and/or after the variation and/or adjustment of the first control variable. For example, conditioned upon the at least partial match not existing at block 608, method 600 may comprise adjusting a second control variable (see block 614); and repeating one or more blocks of method 600. For example, after adjustment of the second control variable, method 600 may return to block 604 and once again vary (e.g., scan) the frequency via the first control variable. The adjustment of the second control variable may be done in the event where the magnitude of the error is so great that the correction cannot be achieved by adjustment of the first variable alone. Hence, the adjustment of the second control variable may change a range over which the frequency of the laser light can be varied by controllably varying the first control variable.

The controlling of the frequency of the laser light may comprise: monitoring the measured physical property associated with reference medium 16 while at least some of the laser light is directed toward reference medium 16; and adjusting the first control variable based on an error (i.e., deviation) between the monitored measured physical property and the set point value. In various embodiments, the first control variable may comprise the length of laser cavity 26 and the second control variable may comprise the drive current to laser diode 24, the temperature of laser diode 24 and/or the temperature inside of enclosure 30. As mentioned above, enclosure 30 may comprise laser diode 24, reference medium 16, laser cavity 26 and/or other components and the control of the temperature inside of enclosure 30 may contribute to the overall stability of laser system 10, 100, 200, 300.

Method 600 may comprise monitoring a pressure inside enclosure 30. As described above, method 600 may comprise compensating for the change in pressure (e.g., using calibration data stored in memory 38) by adjusting one or more control variables associated with the operation of laser system 10. Alternatively or in addition, depending on the magnitude of the pressure change inside of enclosure 30, method 600 may comprise outputting one or more messages to display 40 to alert a user of laser system 10 that the pressure sealing of enclosure 30 may have failed.

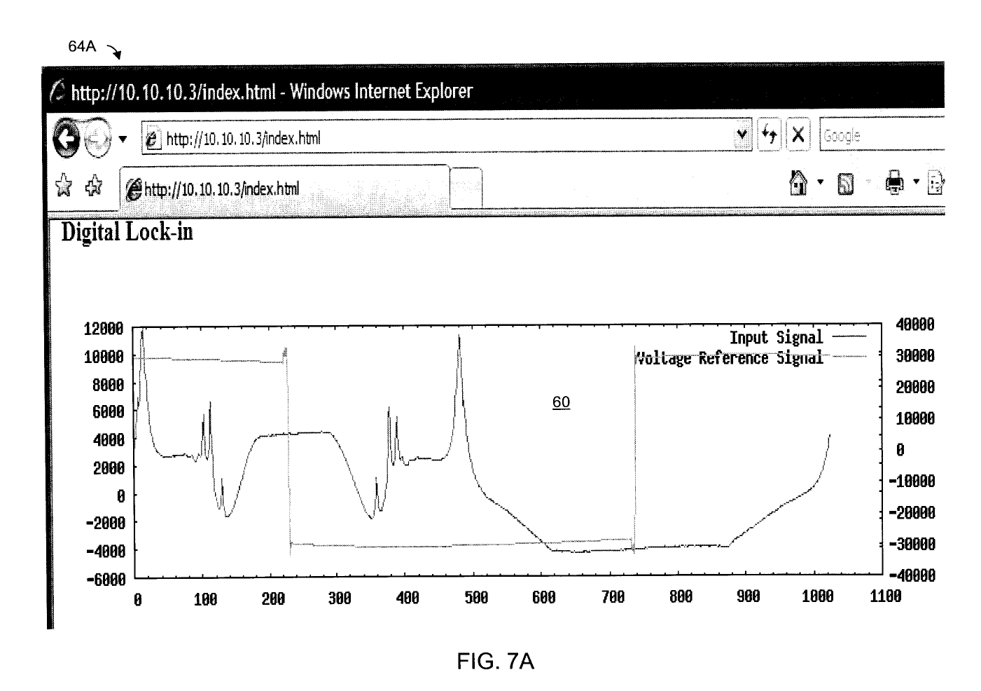

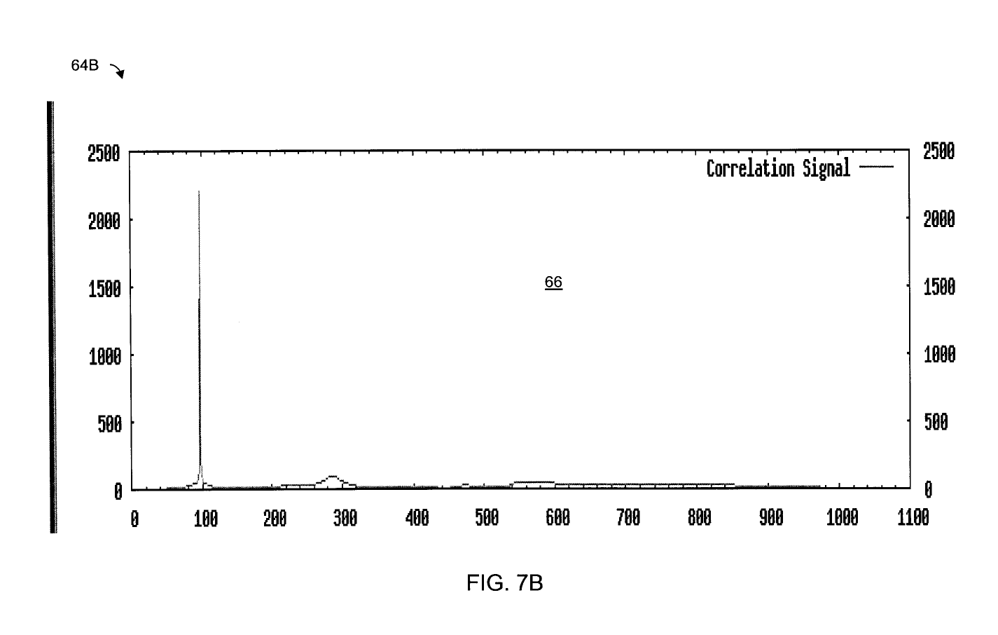

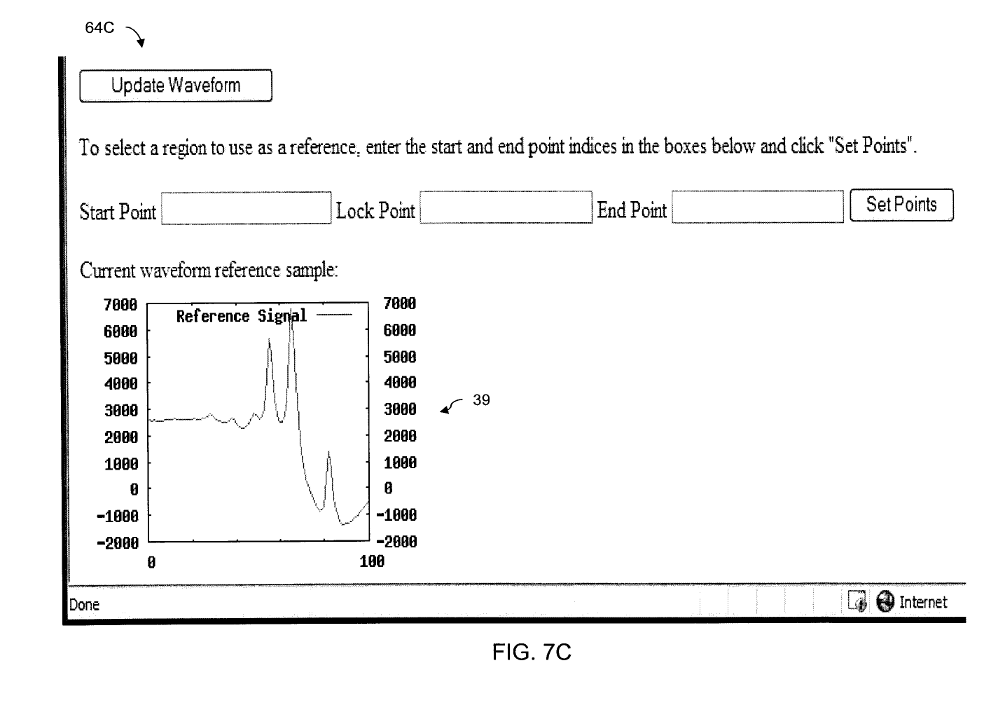

FIGS. 7A-7C collectively show a screen shot of an exemplary graphic user interface including portions 64A-64C, which may be displayed on display 40 during some aspect of the operation of controller 20. Portions 64A-64C may be arranged vertically in graphical user interface 64A-64C. In various embodiments, graphic user interface 64A-64C may show a graphical representation of at least a portion of reference spectrum 39 which may be stored in memory 38. Graphic user interface 64A-64C may also show a graphical representation of at least a portion of measured spectrum 60. As shown in FIG. 7A, reference spectrum may comprise a plurality of potential frequency markers such as absorption/reflection peaks (e.g., atomic or molecular transitions associated with reference medium 16). The frequency marker to which the frequency of the laser light should be locked-onto may correspond to one of the plurality of atomic or molecular transitions associated with the reference medium 16. Also, measured spectrum 60 may comprise more intensity values over a broader range of frequencies than reference spectrum 39. In any event, reference spectrum 39 may comprise sufficient values to permit the identification of reference spectrum 39 within measured spectrum 60. Reference spectrum 39 may, for example, comprise a whole or partial standard data set published the National Institute of Standards and Technology (NIST) for the specific reference medium being used. Alternatively, reference spectrum 39 may have been generated through measurements via detector 18 (e.g., during calibration with another reference device) and may be used subsequently as a baseline reference against which measured spectrum 60 may be compared.

Even though, reference spectrum 39 may comprise a number of peaks, the desired peak to which the frequency of the laser light should be locked onto may initially be selected by a user during start-up for example and the identification of the selected peak may be stored in memory for future use during operation. Accordingly, even though reference spectrum 39 may comprise a plurality of peaks, method 600 may comprise identifying the corresponding peak in measured spectrum 60 which may be used as a set point for controller 20. Plot 66 in FIG. 7B shows a correlation signal which identified which portion of measured spectrum 60 at which a match with reference spectrum 39 has been identified.

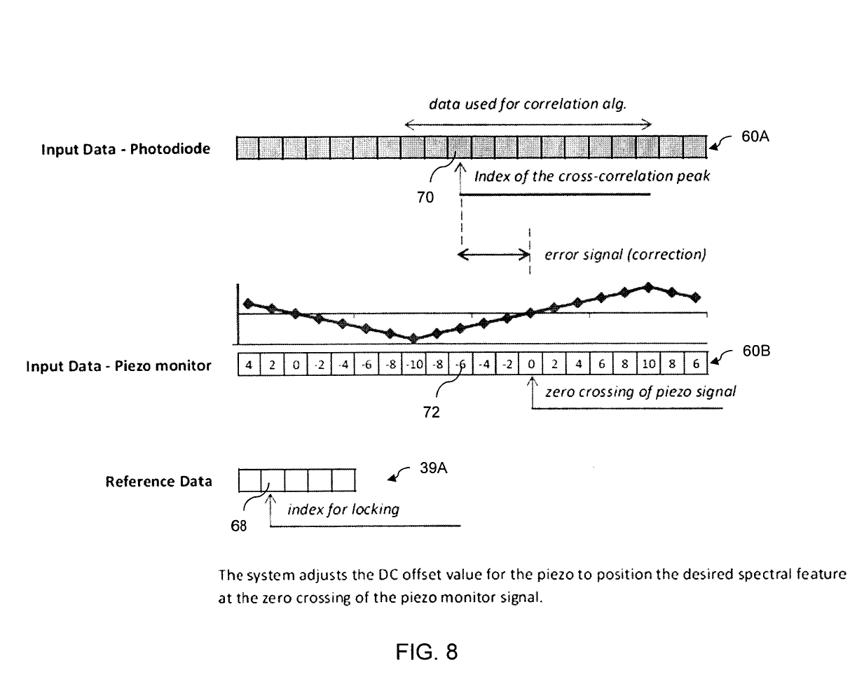

FIG. 8 shows a schematic representation of measured spectrum 60 and reference spectrum 39 of the physical property associated with reference medium 16 used in controlling the frequency of laser light. During acquisition of measured spectrum 60, detector 18 may record the intensity 60A of laser light passing through or being reflected from reference medium 16 depending on the type of reference medium 16 as a function of a scan value 60B that scans the laser frequency. Scan value 60B may correspond to one or more control variables that may be controllably varied in order to vary the frequency of the laser light during the acquisition of measured spectrum 60. For example, scan value 60B may correspond to a voltage applied to one or more piezoelectric transducers (e.g., actuator 28) in order to change the length of laser cavity 26. Accordingly, measured spectrum 60 may comprise intensity values 60A as a function of scan values 60B (e.g., voltage to piezoelectric transducer(s)).

Intensity values 60A and scan values 60B may each comprise linear arrays as illustrated in FIG. 8. Scan values 60B may comprise a ramping up and down of a control signal (i.e., voltage) applied to actuator 28 in a saw tooth manner. In various embodiments, intensity values 60A and scan values 60B may be acquired via separate channels of analog to digital converter 42 and may require to be subsequently correlated to each other. The correlation of intensity values 60A with corresponding scan values 60B may be conducted using known or other algorithms in order to obtain intensity values 60A versus corresponding scan values 60B. For example, the correlation of intensity values 60A and scan values 60B may be conducted using a sliding correlation algorithm.

Intensity values 60A of measured spectrum 60 may also be compared with intensity values 39A of reference spectrum 39 to determine whether a match exists between the two spectra and also to identify the selected frequency marker. Intensity values 39A may also comprise a linear array. The comparison between intensity values 60A and intensity values 39A may be conducted using known or other pattern-matching algorithms. For example, the comparison may be conducted using a thresholding algorithm. Instead or in addition, the comparison may be conducted using a center-of-mass algorithm which may be used to determine whether a center of mass of a portion of intensity values 60A may be within an acceptable tolerance from a center of mass of a portion of intensity values 39A. The thresholding operation may be conducted as a preliminary check to determine whether the center-of-mass operation should be subsequently conducted to confirm whether a match exists. Alternatively or in addition, a sliding correlation algorithm may also be used to determine whether a match exists between measured spectrum 60 and reference spectrum 39.

Once a match is found between measured intensity values 60A and reference intensity values 39A, preselected intensity value 68 in reference intensity values 39A may be correlated to a corresponding target intensity value 70 in measured intensity values 60A. Target intensity value 70 may be used by controller 20 as a set point at which the laser light intensity measured via detector 18 should be maintained. Target intensity value 70 may in turn be correlated to scan value 72, which may, for example, correspond to a length of laser cavity 26 corresponding to target intensity value 70 to be used as a set point. Accordingly, controller 20 may use scan value 72 as an initial value for the first control variable in order to initiate control of the frequency of the laser light (i.e., engage a feedback loop of controller 20). In other words, closed loop control of the frequency of the laser light may be initiated using target intensity value 70 as a set point and using scan value 72 as a starting value for the first control variable (e.g., length of laser cavity 26). It should be understood that the above description is exemplary only and that similar approaches may be used to correlate target intensity value 70 to other control variables that may be used. For example, as mentioned above, control of the frequency of the laser light may be achieved by adjustment of one or more control variables including the length of laser cavity 26, a drive current to laser diode 24, and a temperature of laser diode 24.

In various embodiments, first control variable may initially be calibrated such that a zero crossing of scan value 608 may correspond to a desired laser light frequency to be output by laser system 10. Accordingly, the input linear arrays 60A, 60B may be segmented into linear sections using the sign of the scan signal 60B. The indices of the zero crossings of the scan signal 60B may be found and stored. In the event of an absorption or reflection peak being used as a frequency marker, the sliding correlation operation may then calculate a signal which contains a sharp, well-resolved peak if the measured intensity values 60A include the reference spectrum 39 as a sub-section. The position of the corresponding peak in measured intensity values 60A may be determined by first thresholding a correlation array and then performing a center-of-mass computation. If the index of measured intensity value 70 does not correspond to the index of the zero-crossing of scan signal 60B, this may be indicative of the laser light frequency not being on the target frequency. An error signal may be calculated based on the distance between the indices of the zero crossing of scan signal 60B and measured intensity value 70. This error signal may be used to adjust one or more of the control variables. Plot 66 shown in FIG. 7B shows a correlation array which highlights (see sharp peak) the portion of measured spectrum 60 with which reference spectrum 39 has been found to match.

In various embodiments, the adjustment of a plurality of control variables may be conducted separately or synchronously. Controller 20 may be configured to conduct closed-loop feedback control and/or feed-forward control. For example, a feed forward control mechanism may be used to vary/adjust the drive current to laser diode 24 synchronously with the voltage applied to a piezoelectric transducer attached to laser cavity 26. For example, such feed-forward mechanism may allow modes associated with internal and external cavities of an external cavity diode laser to be tuned in unison resulting in an extended mode hop free tuning range.

Reference spectrum 39 may comprise a library of stored peak signatures consisting of waveform shapes with precisely known frequency marker locations. Each known signature may be iteratively convolved with the incoming signal from detector 18 (i.e., portions of measured spectrum 60) with varying delays over the length of the scan (e.g., sliding correlation) to determine if any recognizable peaks are in the scan range. This may be done by thresholding the result of the sliding correlation step against a pre-set threshold value. Once controller 20 finds a recognized peak, controller 20 may then adjust the control variables around the peak of interest and initiate the high-speed, frequency-locking operating regime. The output of the correlation algorithm is the identification and frequency of the spectral feature that the laser system is currently locked on and the measured deviation of the central frequency of the laser system from the displayed frequency value. The value of the deviation is used in a feedback loop to correct the control variables of laser system 10 and may also logged for diagnostic purposes.

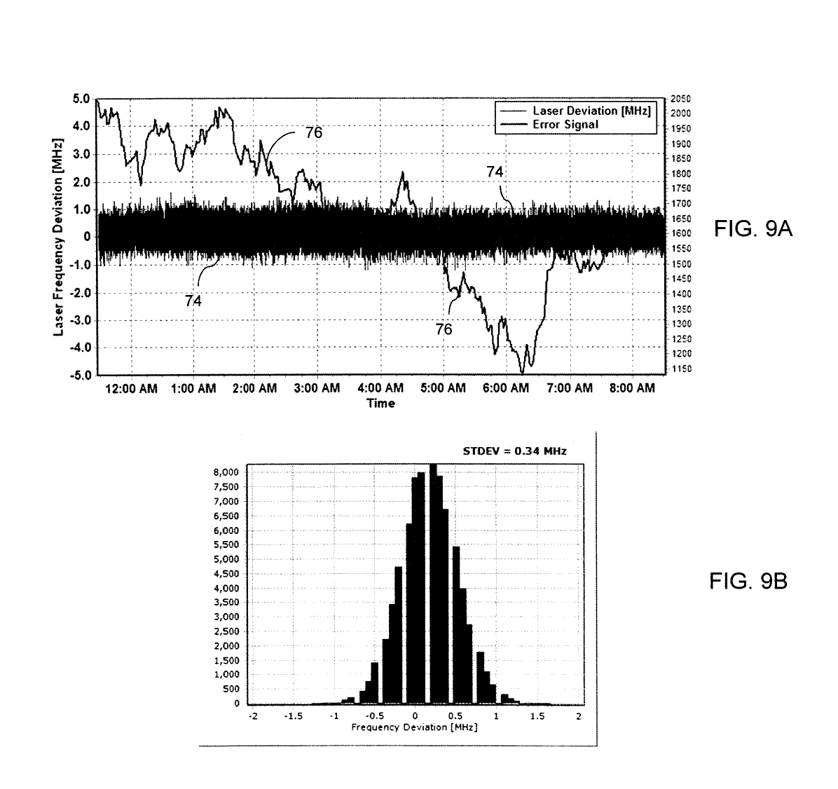

FIGS. 9A and 9B show exemplary plots illustrating stability in the frequency of laser light during control of the frequency of the laser light using an exemplary laser system (i.e., ECDL) in accordance with the present disclosure. The exemplary laser system comprised a digital auto-locking controller to lock the frequency of the output laser light without human intervention. The controller used a digital signal processor to perform pattern matching between Doppler-free spectra obtained by scanning the laser frequency (e.g., measured spectrum 60) and reference peaks (e.g., reference spectrum 39) stored in the controller's memory 38. The incoming light intensity signals were compared with scan values using a sliding correlation algorithm. This technique was used to determine the frequency offset between the measured spectrum 60 and the reference spectrum 39. The offset was fed back as a control voltage to a piezoelectric transducer that was used to adjust the length of the laser cavity of the exemplary laser system. As a result, the laser frequency was iteratively brought closer to the desired frequency. This exemplary laser system was able to search for the desired transition over the available frequency range of ˜10 GHz (in Rb vapor) and automatically relock even in the event of a mode hop because it was also programmed to vary the drive current to the diode laser and also the temperature of the diode laser. In this particular example, the laser system comprised a laser head having a Littrow configuration.

FIG. 9A shows a plot of the frequency (MHz) (see plot 74) of the laser light output by the exemplary laser system 10 as a function of time over about eight (8) hours when the laser system was locked to a frequency corresponding to a wavelength of about 780 nm using a rubidium cell as reference medium 16. Plot 74 represents the frequency deviation of the output laser light relative to the center of the spectral line used as a frequency marker for stabilization. FIG. 9A also shows a plot of the error signal (see plot 76) used by the frequency controller in order to stabilize the frequency. FIG. 9B shows a histogram illustrating the stability of the frequency with a standard deviation of about 0.34 MHz.

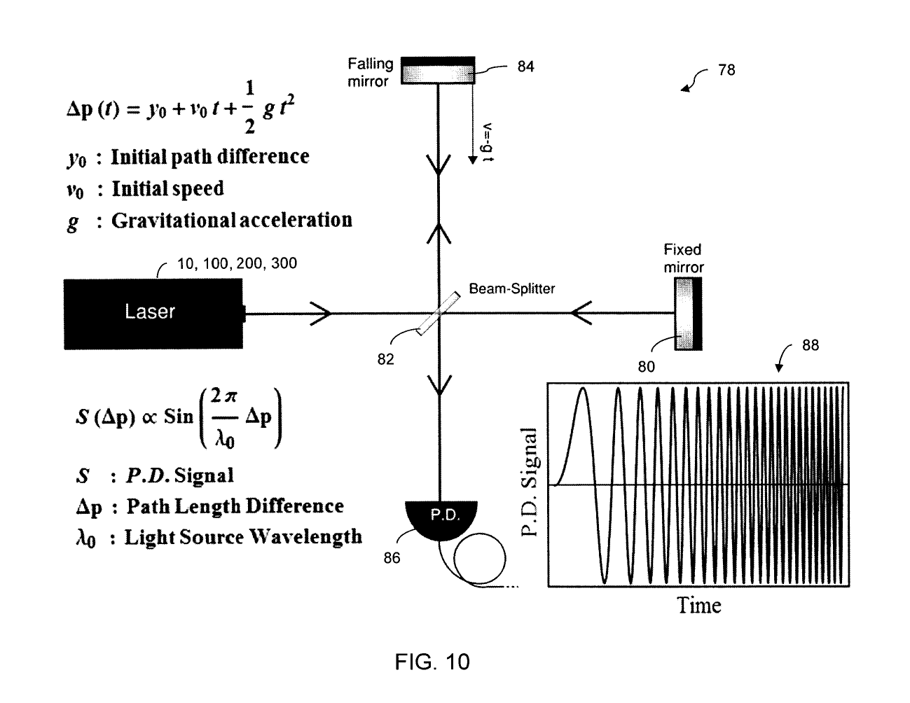

FIG. 10 shows a schematic representation of a gravity meter, generally shown at 78 comprising laser system 10 in accordance with the present disclosure. Laser system 10 may direct frequency-stabilized laser light toward an opposed fixed mirror 80. Beam splitter 82 may be disposed in the optical path between laser system 10 and fixed mirror 80 in order to direct some of the laser light toward falling mirror 84, which may be coupled to a proof mass falling under the influence of gravity. Detector(s) 86 may be configured to detect laser light reflected from falling mirror 84 and also from fixed mirror 80 via beam splitter 82. Signal(s) 88 detected by detector(s) 86 may be used to measure the rate at which falling mirror 84 is falling and hence obtain one or more measurements representative of gravity according to known or other methods.

Laser system 10 may be used in various applications including gravity measurements. Gravity is one of the most important and familiar forces of nature. Precise knowledge of this basic force is of paramount importance not only for fundamental science, but also for applied science and technology. In various embodiments, laser system 10 may be used as an auto-locked diode laser system that can reduce the cost of industrial gravity meters. For example, laser system 10 may be integrated in commercial gravity meters including portable and industrial gravity meters.

Gravity meters are sensitive to variations in the value of the acceleration due to gravity (g) on the earth's surface. They can be designed to measure the absolute value of g or relative changes due to temporal effects such as tides and positional variations due to changes in density. Therefore, gravity meters play a ubiquitous role in the exploration of natural resources by detecting characteristic density profiles associated with minerals, petroleum, and natural gas. The importance of gravity meters for industry lies in their ability to provide a noninvasive technique for exploration in wide area (air, sea or submersible) mineral assays and borehole mapping for verifying properties of rocks, determinations of bulk density detection of cavities and tidal forecasts. They are also used for seismic monitoring of environmentally sensitive areas that are designated for resource extraction. Reducing the cost of gravity meters and improving the accuracy of data provided by these devices has a direct impact on the exploration of new mineral resources by achieving improvements in the reliability of extraction techniques so that environmental footprints are minimized, and resource extraction is optimized. Gravity meters similarly affect the mapping and extraction of oil and natural gas.

For example, the apparatus and methods described herein may be used for tidal monitoring. The value of gravity “g” can show small changes with time over 24 hours due to the “gravity pull” of the sun and moon as they pass overhead. The pull stretches the earth and causes tides. A gravimeter can measure changes in gravity with relatively high precision. The measured changes may be correlated with tides. Gravity measurements can be used to predict and correct tides at any location on the earth. Usually, tidal charts are accumulated using years of observation. A gravity map can be more accurate and can be recorded in a short period of time. Such monitoring may also be used for tracking glacial melting due to global warming.

Gravity meters have also been important for the discovery of new deposits of natural gas and oil in shale deposits throughout Canada. Technologically advanced devices used for communication such as computers and cell phones, and sensitive equipment used for defense are reliant on a particular class of minerals known as rare earths that are widely dispersed in small concentrations. It is evident that several countries including Canada are working actively to explore and secure adequate supplies of these minerals. In Canada, the efforts may focus on large deposits in ecologically sensitive and remote areas in the Northwest Territories. The interest in rare earths is but one example of the importance of exploring new mineral resources.

Falling corner cube absolute gravity meters are typically relatively precise portable gravity sensors. This type of device can be based on an optical Mach-Zehnder interferometer in which one arm containing a retro-reflecting corner cube falls in gravity. Measurements of g precise to ˜1 ppb have been realized by recording the accumulation of fringes over a drop height of ˜0.3 m. The accuracy may depend on the frequency stability of a 633 nm He—Ne laser typically used for interferometry. This type of laser has a power output of ˜100 W, a line width of ˜10 KHz and a frequency stability of ˜10⁻¹¹ that is traceable to a primary frequency standard. It is frequency stabilized by locking to molecular transitions in iodine. Lower cost gravity meters (precise to 20-50 ppb) that are sold in larger volumes also utilize similar laser sources that have a traceable calibration.

Laser frequency drifts in conventional laser systems can occur due to changes in temperature and pressure that may affect the length of an external cavity associated with such laser systems. Typical approaches for frequency stabilization can have restricted lock ranges and can require frequent human interventions to reset the lock even under laboratory conditions. Therefore, typical approaches may not be suitable for locking lasers used in gravity meters under field conditions. In various embodiments, laser system 10 may be used in replacement of other types of laser systems typically used in commercial gravity meters.

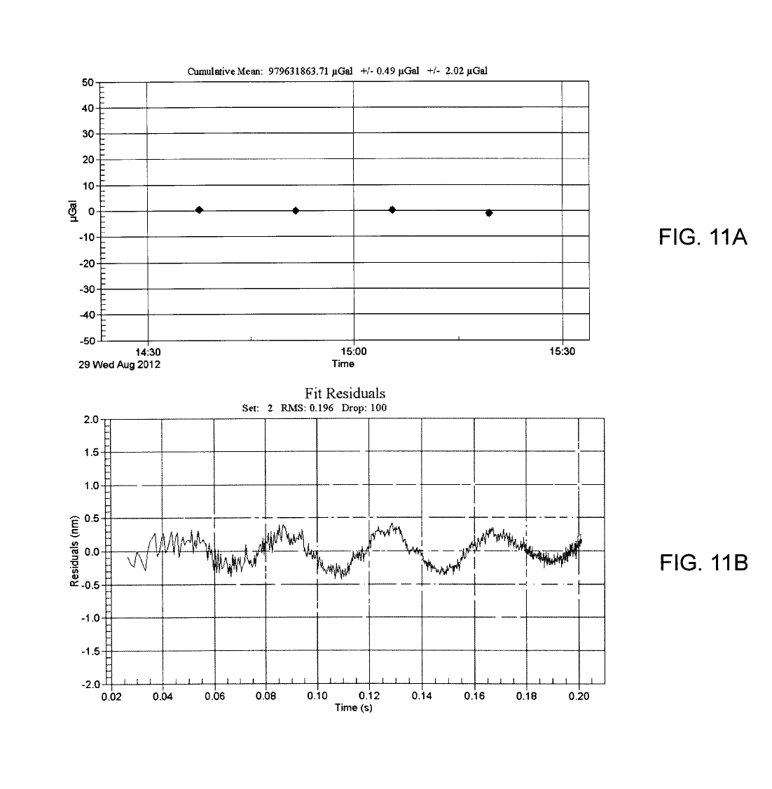

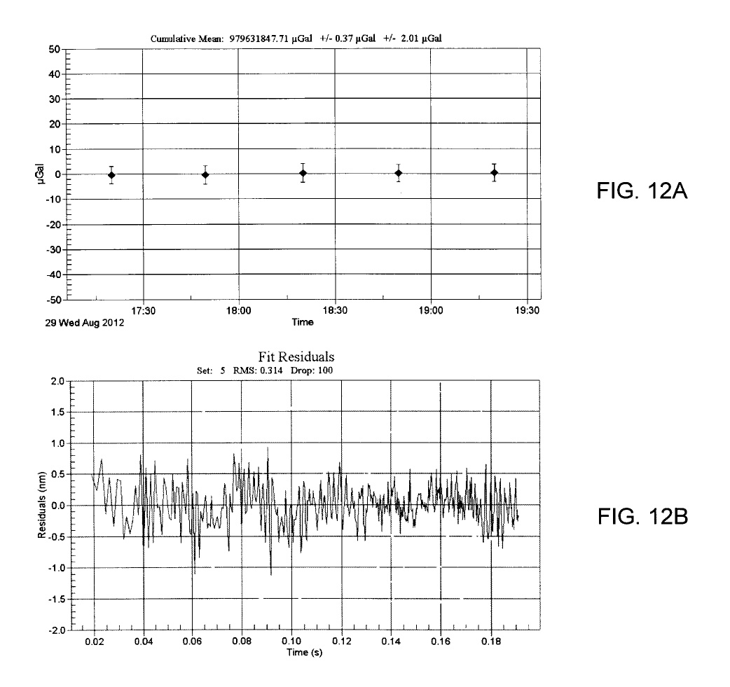

FIGS. 11A, 11B, 12A and 12B show gravimetric results obtained with a FG-5 Autograv™ gravity meter that typically has an absolute accuracy of 1 ppb. Measurements of g were obtained over extended time windows lasting up to 24 hours. This time window was segmented into one-hour slots in which data was obtained by alternately coupling light from either a standard iodine-stabilized He—Ne laser operating at 633 nm or one of the auto-locked laser system 10 operating at 780 nm. The FG-5 Autograv™ gravity meter is based on an optical Mach Zehnder interferometer in which one arm containing a corner cube reflector is allowed to fall through a drop height of 30 cm within a vacuum chamber. The measurement of g relied on recording the chirped accumulation of fringes. In practice, a small fraction of the zero crossings of this fringe pattern are counted as a function of drop time to construct a parabolic fit from which g is extracted. The fitting routine was programmed to subtract the modulation of either laser system. This algorithm also removed other systematic effects such as tidal variations and gravity gradients so that the base line represents the known value of g based on measurements obtained with other gravity meters. The deviation from this baseline (labeled in μGal, where 1 μGal=10⁻⁸ m/s² or 1 ppb of g) is a measure of long-term laser stability.

FIG. 11A shows measurements obtained with the commercial iodine-stabilized He—Ne laser. The graph is labeled by the value of g, which has a systematic uncertainty of 0.49 ppb and a statistical uncertainty of 2.02 ppb. FIG. 11B shows the characteristic fit residuals in nm (data-fit) for a single drop with this commercial laser system.

FIGS. 12A and 12B show gravity measurements and typical residuals using laser system 10 in accordance with the present disclosure and operating at 780 nm. These measurements had similar systematic (0.37 ppb) and statistical uncertainties (2.02 ppb) as the measurements obtained using the commercial iodine-stabilized He—Ne laser. The residuals are also comparable to those obtained using the commercial iodine-stabilized He—Ne laser.

Laser system 10 may be used in a variety of applications. Such applications may include: narrow line width research grade lasers for the physical sciences and metrology (e.g., laser interferometers, laser trackers, laser scanners); low cost lasers for instructional modules and seed lasers for tapered amplifiers; and lidar systems. Laser system 10 may be used for educational (e.g., teaching) activity(ies)/application(s) and may be part of educational kits in combination with instructional/lab manual(s) in the form of one or more electronic or printed documents (i.e., instructional documentation). Such instructional documentation may relate to the operation, maintenance, areas/applications of use and/or other aspects relating to laser system 10. For example, laser system 10 may be used by educational institutions during spectroscopy and atom trapping lab courses consisting multiple instructional modules (lab experiments) that teach hands-on training.

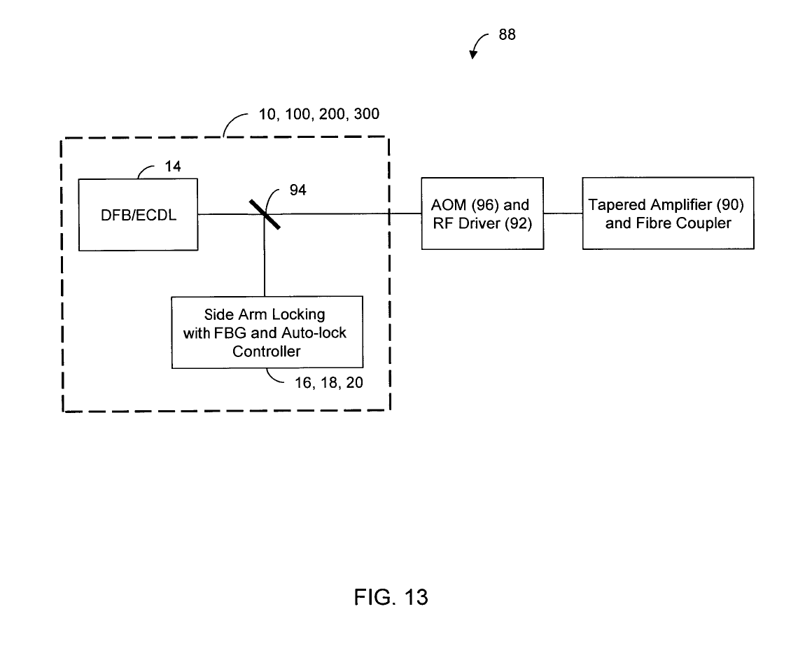

FIG. 13 shows a schematic representation of a transmitter, generally shown at 88, of a Laser Interferometry Detection and Ranging (lidar) device comprising laser system 10 in accordance with the present disclosure. Basic lidar measurement technique can involve the comparison of the intensity of laser backscatter at the absorbed wavelength to a reference signal at a second (offline) wavelength that is not absorbed. Conventional lidar devices can require a pulsed laser to hit two spectral lines referred to as on resonance and off resonance points. The pulses generally have a large spectral bandwidth and typically cannot be precisely tuned.

In contrast, a diode laser producing low power (e.g., laser source 14) may be used as a seed laser to seed semiconductor tapered amplifier waveguide 90, which amplifies the light to high power. The amplified light can be pulsed using radio frequency device 92. Such a lidar source may have a much narrower line width than traditional sources and it may be tuned easily and precisely using an auto-lock apparatus such as controller 20. As explained above, tuning may make use of vapor cells or frequency markers from solid state devices that can be compactly integrated.

For example, laser system 10 may be used to seed tapered amplifier 90 for pollution monitoring and detection of water vapor. Laser system 10 may be configured to operate at resonant frequencies of water vapor in the 800 nm band. Frequency doubling this light can produce lidar sources in the 400 nm band to study pollutants such as NO₂. A rugged distributed feedback (DFB) seed laser 14 can also be auto-locked to the desired transitions in a side arm with a temperature-controlled fiber Bragg grating (FBG) 16 (via beam splitter 94) that can provide highly reflective markers (Full Width at Half Maximum (FWHM)˜5 GHz) on either side of the desired resonance and at the offline lock point. Controller 20 may be calibrated using resonance lines from the desired species. The FBGs 16, which have temperature shifts of 5 GHz/K, may be stabilized to within 5 MHz using temperature controllers used for ECDLs 14 described previously. The output of seed laser 14 may be amplitude modulated using an acousto-optic modulator (AOM) 96 and the pulsed output will be amplified using tapered semiconductor amplifier (TA) 90. The output from TA 90 may be fiber coupled and integrated with lidar receivers. For example, laser system 10 may be configured to be integrated into a lidar system and generate output pulses with durations of 1 μsec, a peak power of 1 W, a line width of ˜40 MHz, and a repetition rate of 10 kHz. In various embodiments, the overall frequency uncertainty may be around ˜20 MHz and may be substantially smaller than specifications of commercially available lidar systems.

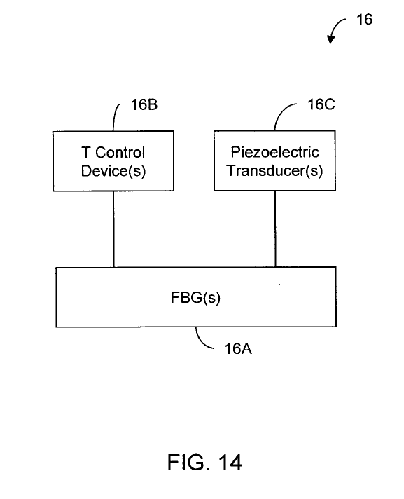

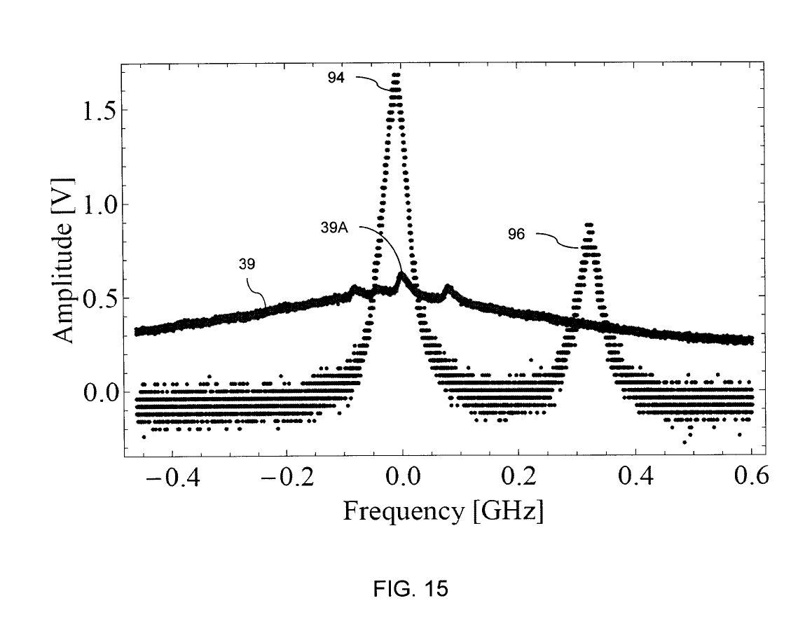

FIG. 14 is a schematic illustration of reference medium 16 of laser system 10 comprising one or more FBG's. Reference medium 16 may comprise FBG 16A, one or more temperature control devices 16B and one or more piezoelectric transducers 16C or other type of actuator(s) suitable for straining FBG 16A. In some embodiments, FBG 16A may be used instead of a vapor cell. FBG 16A may be configured to exhibit one or more reflection notches (see notches 94, 96 in FIG. 15). For example, FBG 16A may comprise a dual notch FBG. FBG 16A may be configured and tuned to have a reflection notch at or near a wavelength of 780 nm so as to eliminate the need for a rubidium vapor cell. Similarly, FBG 16A may be configured and tuned to have a reflection notch at or near 633 nm so as to eliminate the need for an iodine vapor cell. Accordingly, FBG 16A may be tuned to have a reflection notch at or near a desired wavelength/frequency to serve as a frequency marker and the output frequency of laser light from laser system 10 may be controlled based on (e.g., locked onto) the reflection notch of FBG 16A.

Tuning of FBG 16A may be achieved by varying the temperature of FBG 16A and/or straining FBG 16A in order to vary the wavelength of the light that is reflected by FBG 16A. Accordingly, reference medium 16 may comprise a suitable temperature control device 16B which may be configured to either heat or cool FBG 16A. In some embodiments, temperature control device 16B may comprise a suitable thermoelectric heating and/or cooling device using the Peltier effect. Control of temperature control device 16B may be carried out by controller 20 (see FIG. 2).

Reference medium 16 may instead or in addition comprise piezoelectric actuator 16C that may be used to positively and/or negatively strain FBG 16A. Control of piezoelectric actuator 16C may be carried out by controller 20 (see FIG. 2).

FIG. 15 is a plot showing two FBG reflection notches (peaks) 94, 96 that have been temperature tuned to the vicinity of a reference spectrum 39 at a wavelength of around 780 nm from a 5 cm long vapor cell containing rubidium 87. The x-axis (i.e., frequency) has been adjusted so that the point of reference (i.e., 0 GHz) is substantially coincident with the highest peak 39A of reference spectrum 39. The use of FBG 16A in reference medium 16 may have advantageous properties when used in lidar systems. As explained above, lidar measurements can involve the comparison of the intensity of backscatter at the absorbed wavelength of interest (online or set point frequency) to a second, different wavelength (offline frequency at a distance from the set point frequency) that is not absorbed. In some applications, the range between the online frequency and the offline frequency may be achievable using the same FBG 16A so that FBG 16A may be tuned to either the online frequency or the offline frequency.

Larger (i.e., online) notch 94 has a width of about 70 MHz. This is comparable to the 10-20 MHz spectral widths in rubidium and iodine and provides a suitably narrow frequency marker for some applications. Larger notch 94 may be used for auto-locking and may represent the online point for use with a lidar source. It may be possible to obtain a relatively narrow line width with laser system 10 by using optical feedback from FBG 16A. The spectral width of the larger (primary) reflective notch 94 from FBG 16A (i.e., about 70 MHz) may be substantially narrower than a spectral width of the reflected light from an interference filter (e.g., about 150 GHz). Therefore, using optical feedback from FBG 16A may be expected to further reduce the line width of laser system 10. In some embodiments, the frequency/position of larger notch 94 may, for example, be varied by adjusting the temperature of FBG 16A using temperature control device 16B. In some embodiments, the frequency/position of smaller notch 96 may be varied by adjusting the strain on FBG 16A using piezoelectric transducer 16C. In the example shown in FIG. 15, smaller notch 96 is about 350 MHz from larger notch 94. Smaller notch 96 may provide an offline point for laser locking and may be of importance for a pulsed lidar source. Spectral widths and spectral frequencies (positions) may be known to relatively high accuracy based on the known frequencies of rubidium lines in reference spectrum 39.

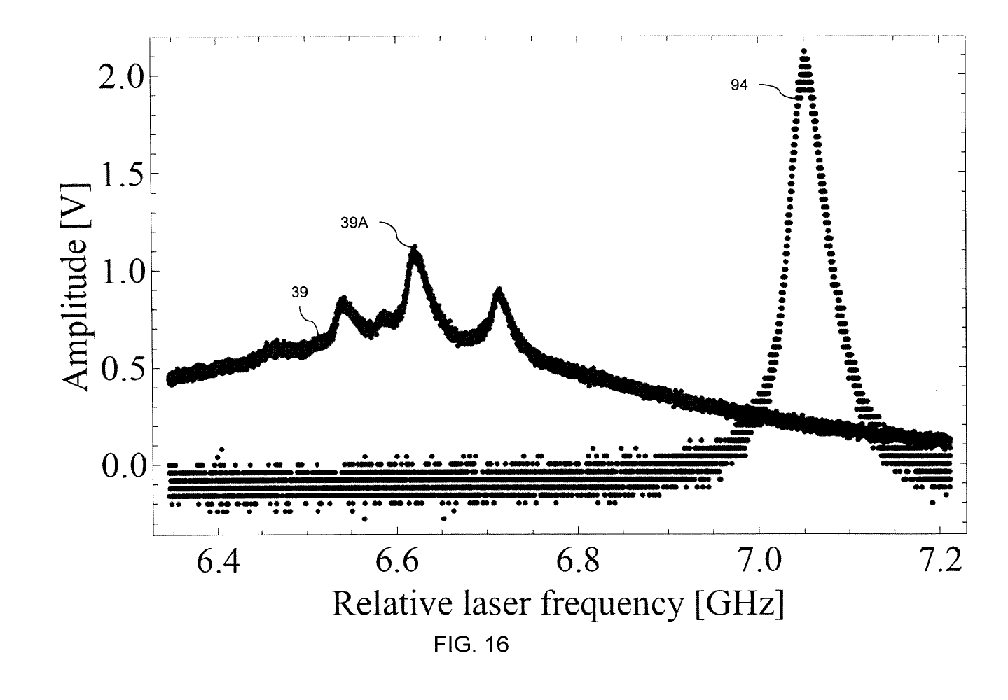

FIG. 16 is a larger magnification plot showing only larger notch 94 exhibited by FBG 16A in relation to reference spectrum 39. The x-axis (i.e., frequency) has been adjusted so that the point of reference (i.e., 0 GHz) is substantially coincident with the highest Doppler-free peak in the lowest-energy manifold of rubidium 87 which is not shown in FIG. 16 since it lies off to the left of the plot of FIG. 16. The plot of FIG. 16 shows an example of the shifting of larger peak 94 to an offline frequency that may be achieved by temperature tuning of FBG 16A.

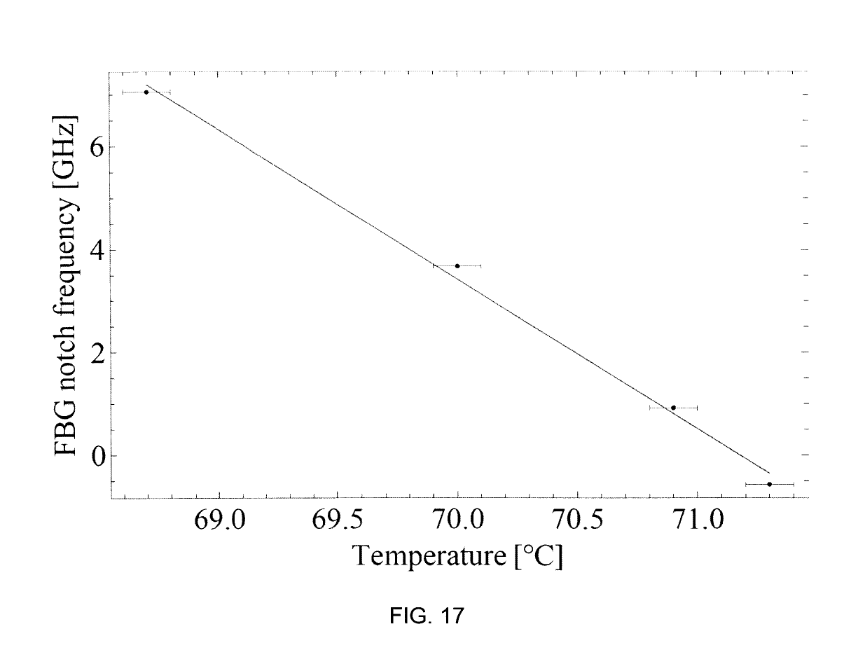

FIG. 17 is a plot of notch frequency for an exemplary FBG 16A versus temperature. The tunability of FBG 16A may permit FBG 16A to be tuned to either the online frequency (e.g., notch 94 in FIGS. 15 and 16) or to the offline frequency (e.g., notch 96 in FIG. 15) so that the same FBG 16A may be used to acquire both the backscatter at the online frequency and the backscatter at the offline frequency using a lidar system. Alternatively, instead of using the same FGB 16A for tuning to the online frequency and offline frequency, two FGB's could be used in laser system 10. For example, a first FGB could be tuned to have a notch frequency at or near the online frequency and a second FGB could be tuned to have a notch frequency at or near the offline frequency so that the output frequency of laser system could be tuned to different FGB's depending on the desired output frequency.

In some applications, the difference between the online frequency and the offline frequency may be around 1-2 GHz and may be achieved by varying the temperature of FBG 16A. Alternatively, using a dual notch FBG 16A, larger notch 94 may be used as a frequency marker for the online frequency and smaller notch 96 may be used as a frequency marker for the offline frequency. As shown in FIG. 17, the FBG notch frequency (e.g., of larger notch 94) may be temperature tuned across the manifold of rubidium spectral lines in the 780 nm band. The rubidium spectra in this band ranges over about 7 GHz and involves spectral lines from both rubidium 85 and rubidium 87 that may be present in the same vapor cell. Accordingly, the known frequencies of the rubidium lines (frequency markers) may be used to tune the reflection notch of FBG 16A and therefore permit the use of FBG 16A instead of a vapor cell in laser system 10. As shown in FIG. 17 the notch frequency of FBG 16A may be varied at the rate of −2.90+/−0.13 GHz per ° C. In some embodiments, controller 20 and temperature control device 16C may be configured to cause the temperature of FBG 16A to be varied in steps of 1/1000° C. so that the notch frequency of FBG 16A may be controlled within about 3 MHz.

In some circumstances where temperature tuning of FBG 16A alone is not sufficient to achieve a desired notch frequency, piezoelectric transducer 16C may be used to strain FBG 16A. Straining of FBG 16A may be done in conjunction with or in addition to temperature tuning.

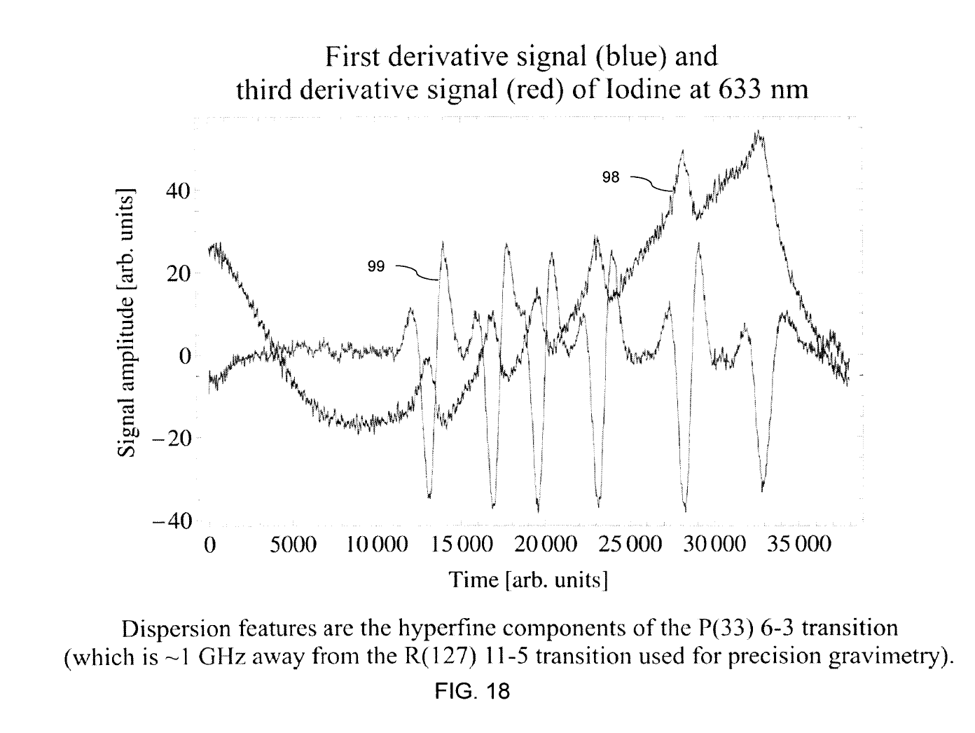

FIG. 18 is a plot showing first derivative 98 and third derivative 99 of measured spectrum 60 obtained from an iodine vapor cell. As explained above, measured spectrum 60 may be compared with reference spectrum 39 in order to determine whether at least a partial match exists between measured spectrum 60 and reference spectrum 39. In situations where the feature(s) of interest on a spectrum is/are relatively easy to identify, the comparison may be made between the spectra 39, 60 in their native form by pattern matching for example. However, in some situations where the feature(s) of interest is/are relatively small and/or difficult to identify, the first derivative and/or the third derivative may be used for comparison instead or in addition. For example, spectral peaks associated with a spectrum obtained using an iodine cell may be relatively small compared to spectral peaks associated with a spectrum obtained using a rubidium cell. For example, a peak of interest in a spectrum obtained from an iodine cell for locking to a 633 nm wavelength may represent 0.1% absorption and a peak of interest in a spectrum obtained from a rubidium cell for locking to a 780 nm wavelength may represent 50% absorption. Accordingly, in some cases, machine-readable instructions stored in memory 38 may be configured to cause processor 36 (see FIG. 2) to obtain/compute first and/or third derivatives of measured spectrum 60 and reference spectrum 39 and then compare the respective derivatives of the measured spectrum 60 and reference spectrum 39 in order to determine whether at least a partial match exists between measured spectrum 60 and reference spectrum 39. Once the first and/or third derivatives are obtained or computed, the determination whether a partial match exists between the two spectra 39, 60 may be made using one or more methods disclosed herein or other suitable methods. The use of the third derivative may allow the center of the spectral lines to be identified with better accuracy.

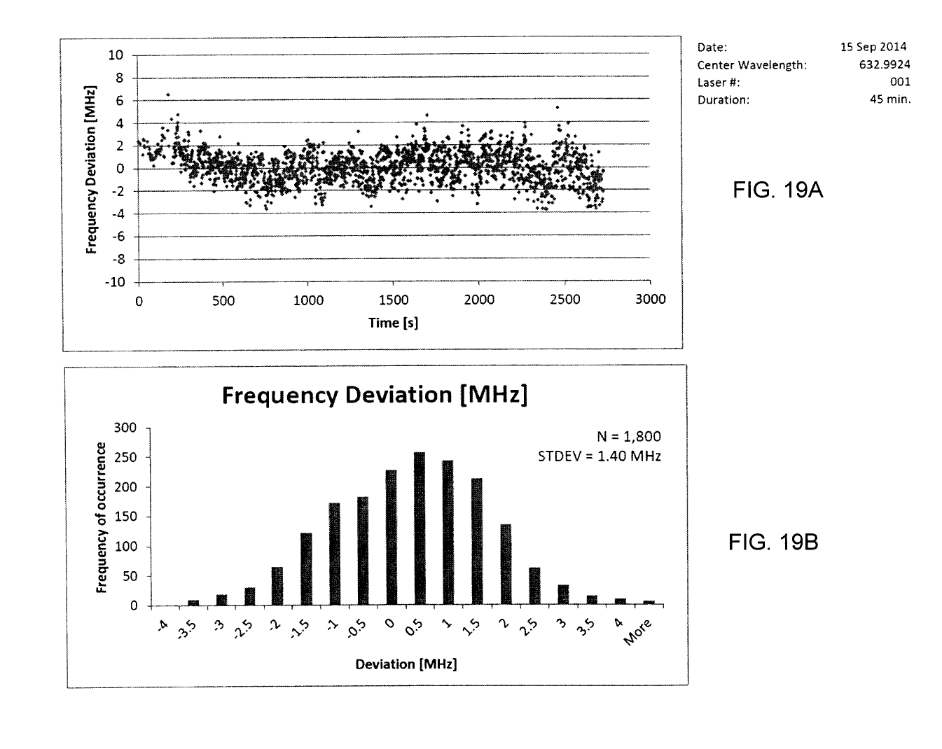

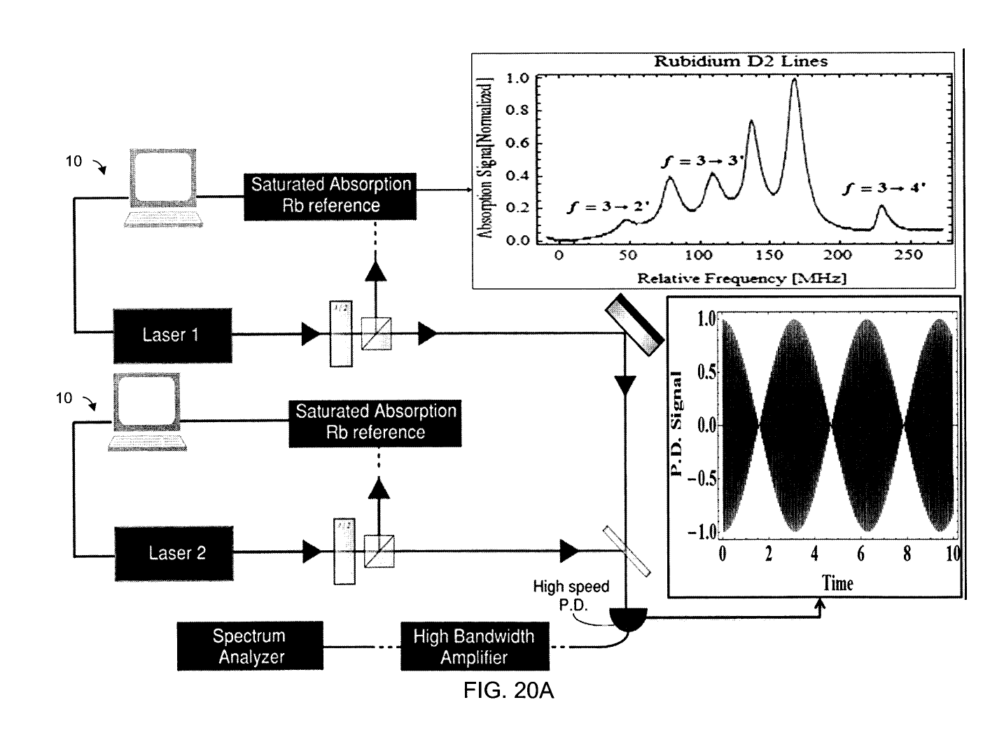

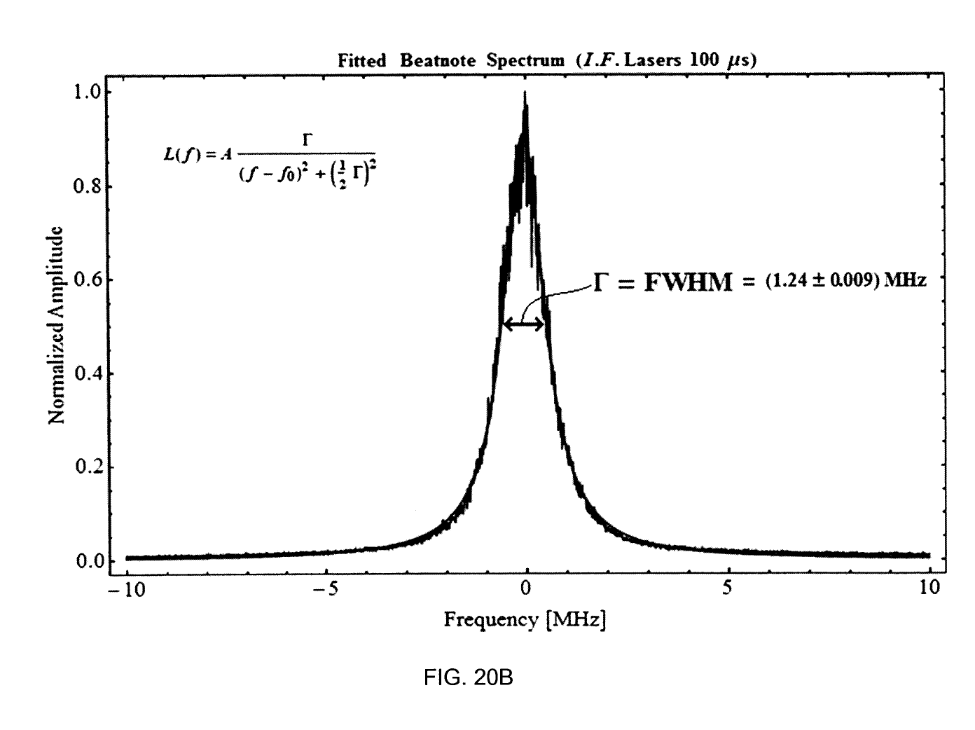

FIG. 19A shows a plot (points) of the frequency (MHz) of the laser light output by the exemplary laser system 10 as a function of time over about 45 minutes when laser system 10 was locked to a frequency corresponding to a wavelength of about 633 nm using an iodine cell as reference medium 16. Plot 74 represents the frequency deviation of the output laser light relative to the center of the spectral line used as a frequency marker for stabilization. FIG. 19B shows a histogram illustrating the stability of the frequency with a standard deviation of about 1.4 MHz. FIG. 20A shows a rubidium saturated absorption set up for monitoring the scan range and long-term performance of an exemplary laser system 10 in accordance with the present disclosure. The mode structure of the exemplary laser system 10 was determined on the basis of beat note tests with an identical laboratory prototype using a spectrum analyzer with an analog bandwidth of several GHz. FIG. 20B shows a representative beat note spectrum with a combined linewidth of 1.24 MHz (FWHM). From a Lorentzian fit, the line width of each laser system could be inferred to be 0.62 MHz. The beat note measurements may be crucial for the suppression of external cavity modes that produce characteristic fringe patterns in gravimeter data.

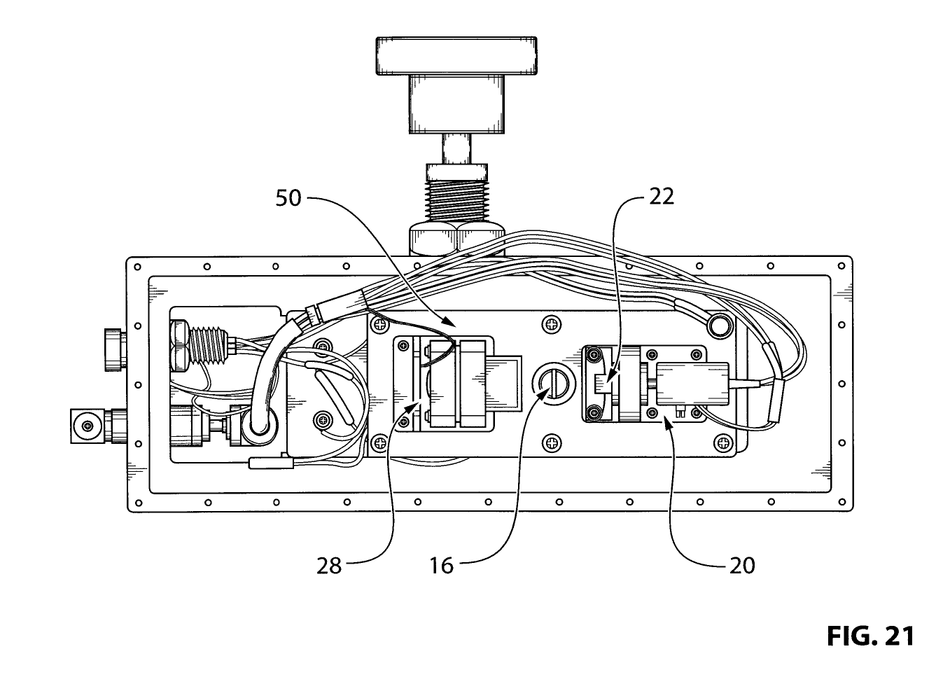

FIG. 21 shows part of an exemplary laser system 10 in accordance with that shown in FIG. 3. FIG. 21 shows reference medium 16 comprising an interference filter configured to provide a frequency marker for outputting laser light around 780 nm. In order to configure laser system 10 to output a different wavelength/frequency, some of the optical components (e.g., reference medium 16) may be substituted with other components configured for such other wavelength/frequency. In some embodiments, the substitution of components may be done without significant disassembly.

For example, reconfiguring laser system 10 to switch from an output wavelength of 780 nm to 633 nm may comprise replacing a rubidium vapor cell with an iodine vapor cell and also replacing one or more optical components with replacement components that are compatible with the new wavelength.

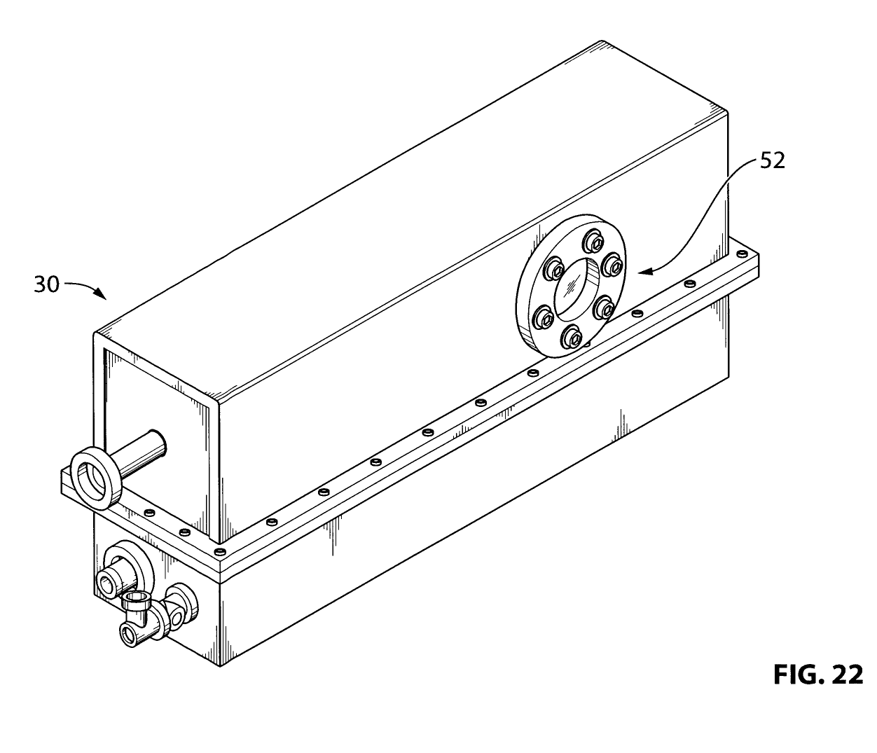

FIG. 22 shows an exemplary enclosure 30 of laser system 10 in accordance with that shown in FIGS. 3 and 21. Enclosure 30 of FIG. 22 may contain the components shown in FIG. 21.

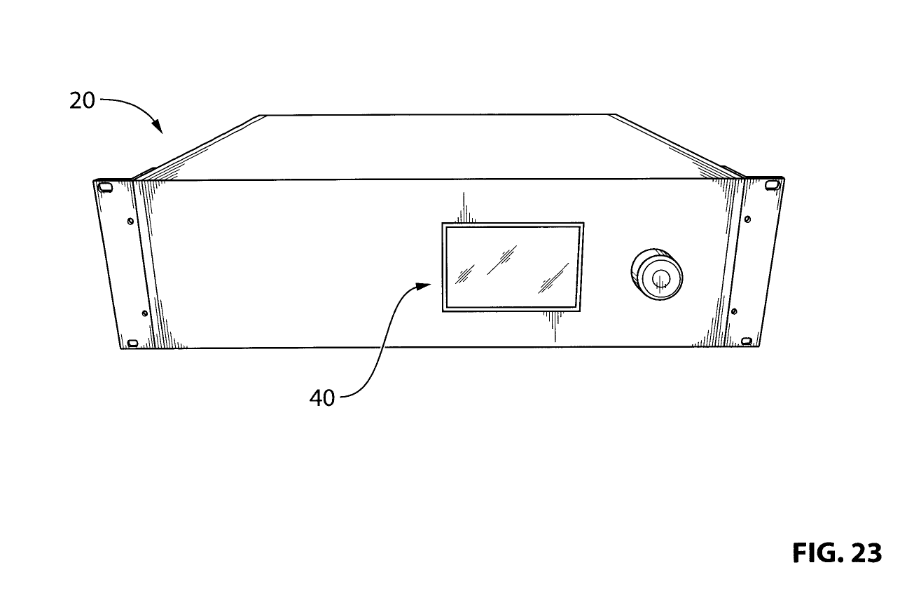

FIG. 23 shows an exemplary controller 20 of laser system 10 in accordance with the present disclosure. Controller 20 may be operationally coupled with one or more components of laser system 10 as shown in FIG. 2. As previously explained, controller 20 may comprise display 40 or display 40 may be a separate display screen associated with a computer coupled to controller 20. Display 40 may provide summary (e.g., status) information on the operation of laser system 10 including the locked status, maximum frequency deviation and the parameters of the currently locked spectral line. Additional information pages may be selectively displayed on display 40 based on user input. Display 40 may be touch-sensitive in order to receive user input. Alternatively or in addition, some other user-input device may be provided to permit interaction between a user and controller 20. Machine-readable instructions may be entered via user input or uploaded to memory 38 from another source using known or other means.

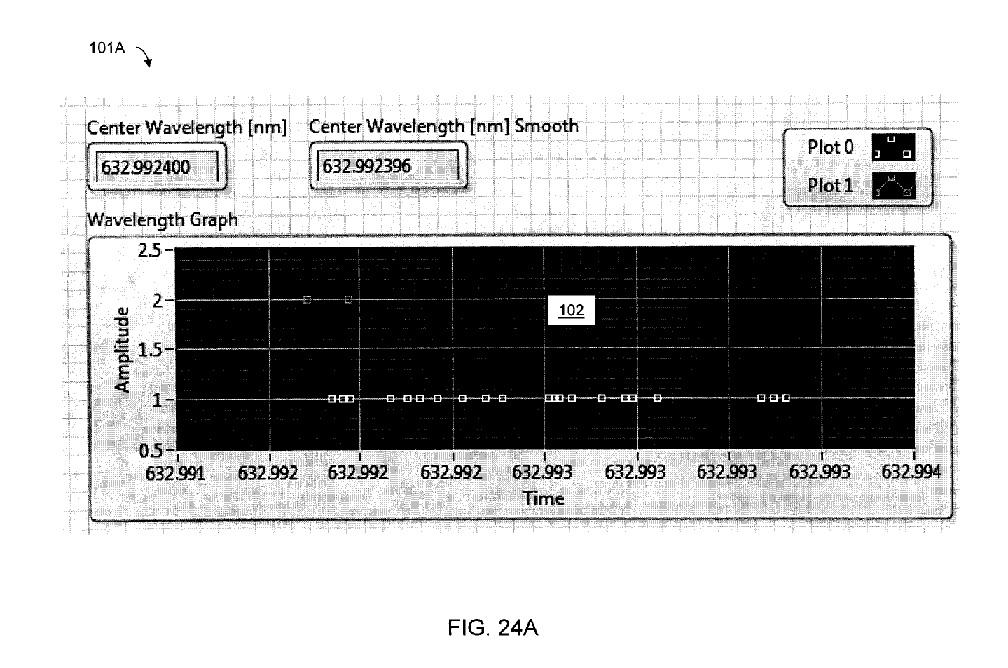

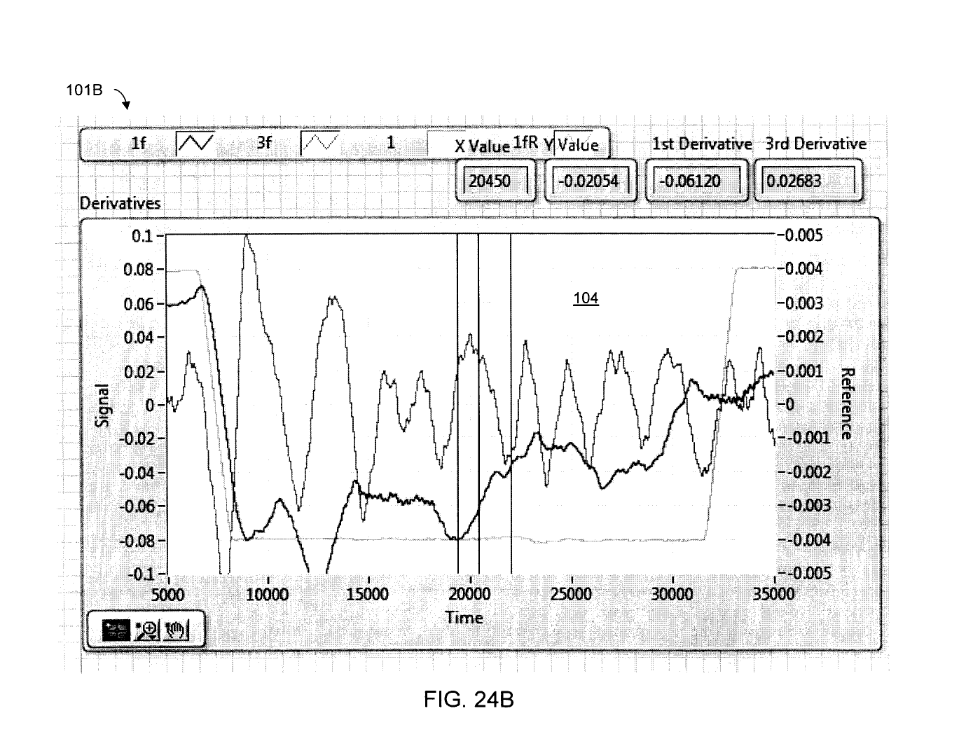

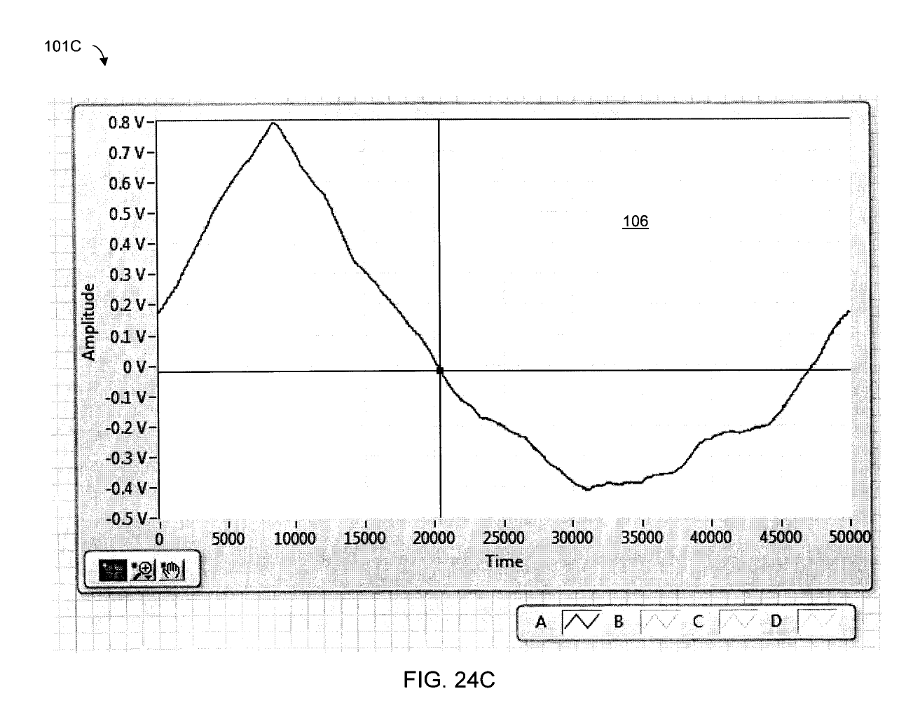

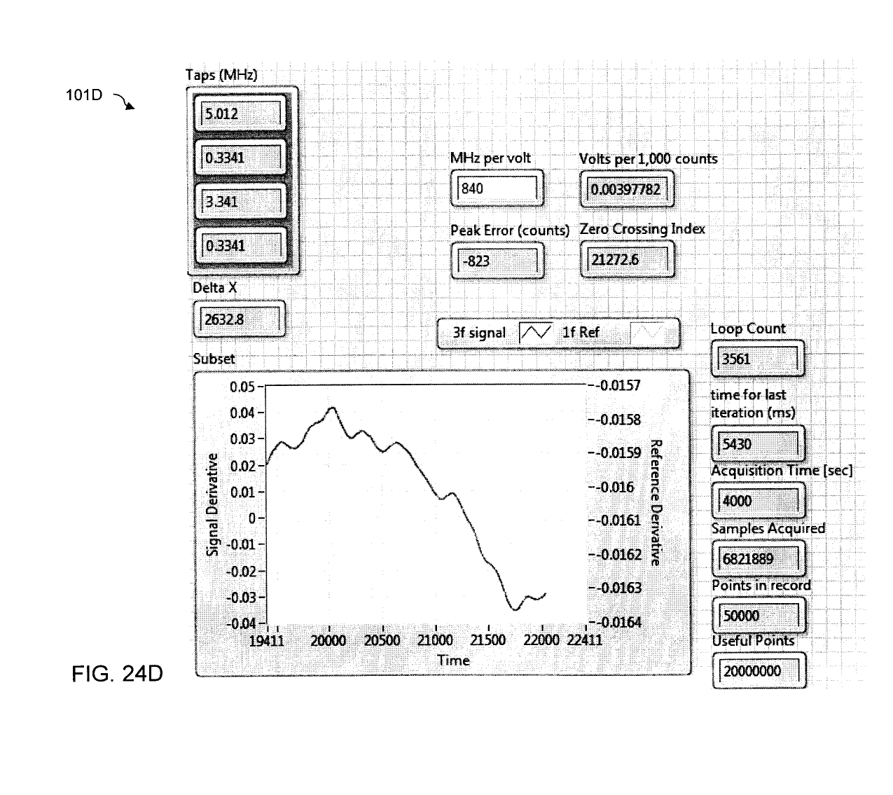

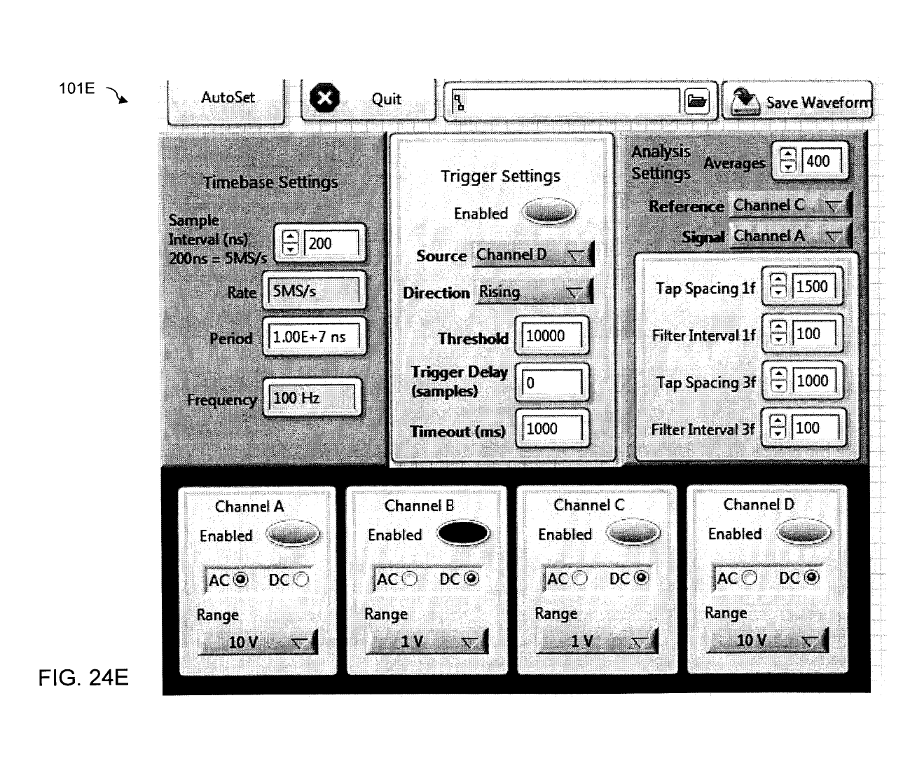

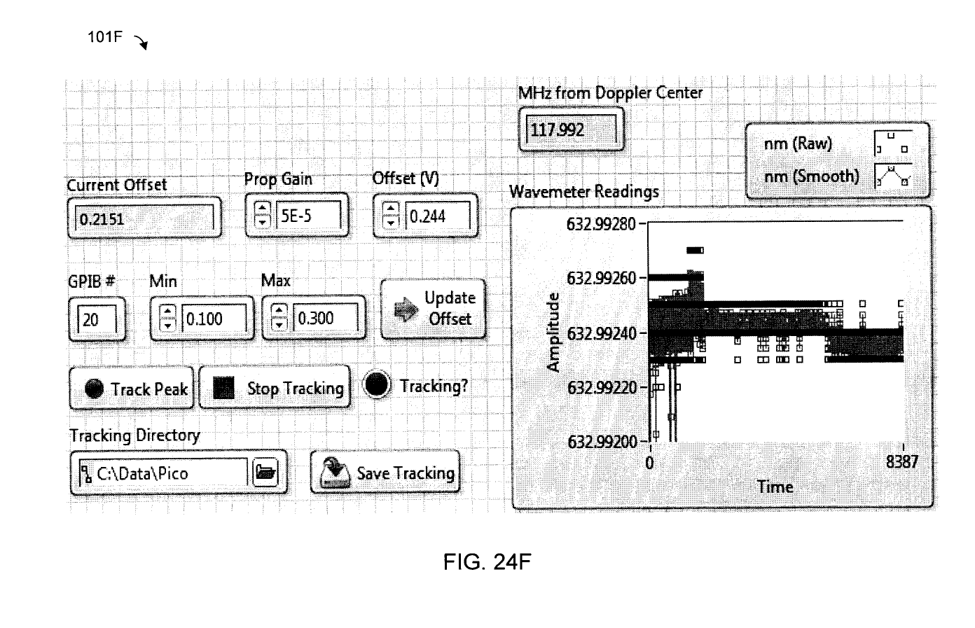

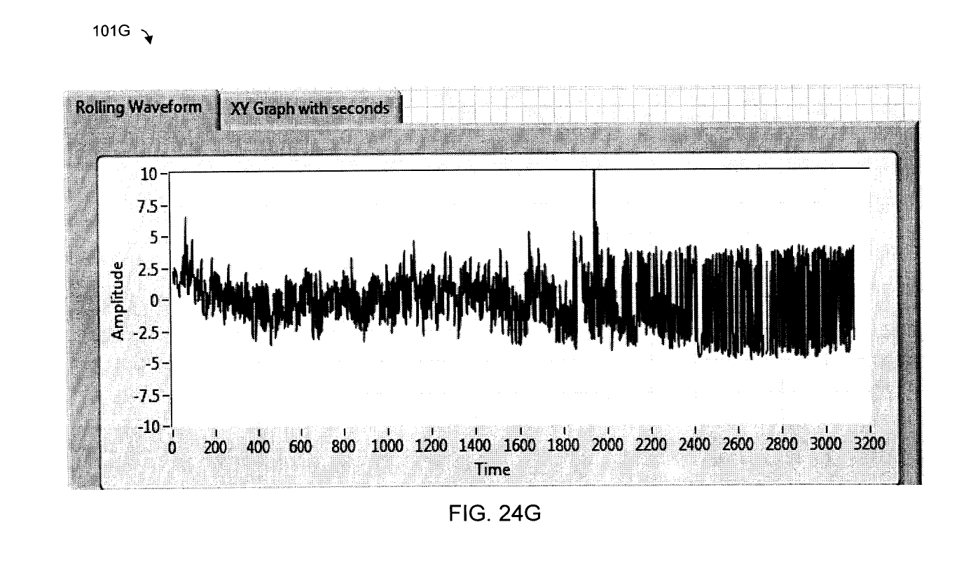

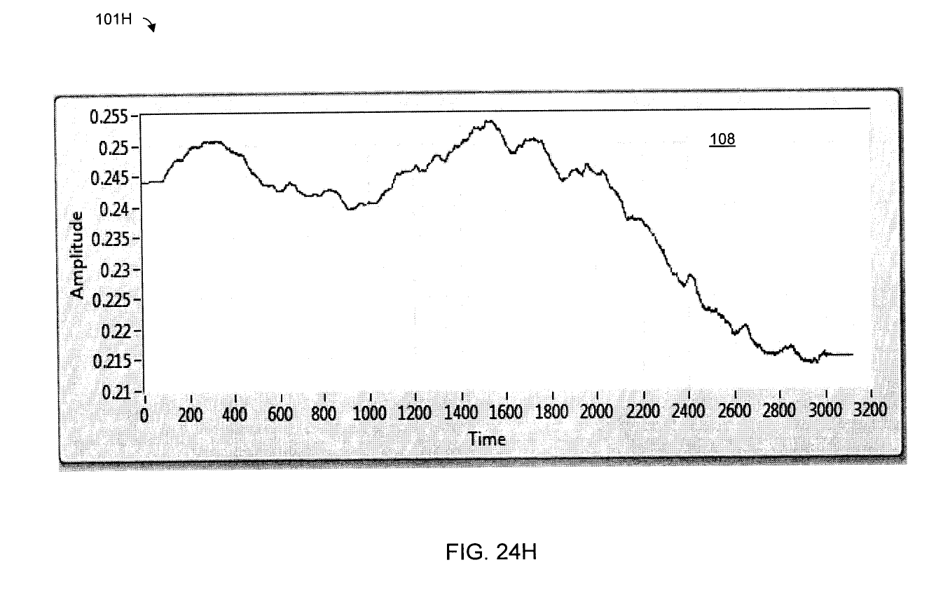

FIG. 24A-24H collectively show a screen shot of another exemplary graphic user interface including portions 101A-101H, which may be displayed on display 40 during some aspect of the operation of controller 20. Portions 101A-101C may be arranged vertically in a left hand part of graphic user interface 101A-101H. Portions 101D-101E may be arranged vertically in a middle part of graphic user interface 101A-101H. Portions 101F-101H may be arranged vertically in a right hand part of graphic user interface 101A-101H. Graphic user interface 101A-101H may be used for monitoring the operation of laser system 10 during operation or during commissioning. In various embodiments, graphic user interface 100 may comprise a plurality of regions 102, 104, 106 and 108 displaying different information relating to the operation of laser system 10. For example, region 102 may display the same information as shown on display 40 of FIG. 23. Region 104 may display plots of the first and/or third derivatives of measured spectrum 60 and/or reference spectrum 39. Region 106 may plot a correlation signal which identified which portion of measured spectrum 60 at which a match with reference spectrum 39 has been identified. Region 108 may plot a rolling waveform indicative of the stability of the frequency locking of laser system 10.

The above description is meant to be exemplary only, and one skilled in the relevant arts will recognize that changes may be made to the embodiments described without departing from the scope of the invention disclosed. For example, the blocks and/or operations in the flowcharts and drawings described herein are for purposes of example only. There may be many variations to these blocks and/or operations without departing from the teachings of the present disclosure. For instance, the blocks may be performed in a differing order, or blocks may be added, deleted, or modified. The present disclosure may be embodied in other specific forms without departing from the subject matter of the claims. Also, one skilled in the relevant arts will appreciate that while the systems, devices and assemblies disclosed and shown herein may comprise a specific number of elements/components, the systems, devices and assemblies could be modified to include additional or fewer of such elements/components. The present disclosure is also intended to cover and embrace all suitable changes in technology. Modifications which fall within the scope of the present invention will be apparent to those skilled in the art, in light of a review of this disclosure, and such modifications are intended to fall within the appended claims.

1. A method for controlling a frequency of laser light based on a reference spectrum of a physical property associated with a reference medium where the reference spectrum comprises a selected frequency marker, the method comprising:
directing at least some of the laser light output by a laser source toward the reference medium;
varying the frequency of the laser light by controllably varying a first control variable;
measuring the physical property associated with the reference medium while the at least some laser light is being directed toward the reference medium and while the first control variable is being varied to generate a measured spectrum of the physical property as a function of the first control variable;
comparing the measured spectrum with the reference spectrum to determine whether at least a partial match exists between the measured spectrum and the reference spectrum; and
conditioned upon the at least partial match existing:
identifying a set point for the measured physical property corresponding to the selected frequency marker in the reference spectrum;
identifying an initial value for the first control variable corresponding to the set point for the measured physical property; and
controlling the frequency of the laser light based on the set point for the measured physical property and the initial value for the first control variable.

2. The method as defined in claim 1, comprising adjusting a second control variable prior to varying the frequency of the laser light via the first control variable.

3. (canceled)

4. The method as defined in claim 2, wherein the adjustment of the second control variable changes a range over which the frequency of the laser light can be varied by controllably varying the first control variable.

5. (canceled)

6. (canceled)

7. The method as defined in claim 1, wherein comparing the measured spectrum with the reference spectrum comprises comparing a center of mass associated with the measured spectrum with a center of mass associated with the reference spectrum.

8.-12. (canceled)

13. The method as defined in claim 1, comprising monitoring a pressure inside an enclosure comprising the laser source and the reference medium.

14. (canceled)

15. The method as defined in claim 1, wherein the frequency marker corresponds to an atomic or molecular transition associated with the reference medium.

16.-23. (canceled)

24. The method as defined in claim 1, wherein the reference medium comprises a fiber Bragg grating (FBG).

25. (canceled)

26. The method as defined in claim 24, comprising tuning the FBG by at least one of adjusting the temperature of the FBG and straining the FBG.

27.-29. (canceled)

30. An apparatus for controlling a frequency of laser light based on a reference spectrum of a physical property associated with a reference medium where the reference spectrum comprises a selected frequency marker, the apparatus comprising:
at least one processor;
at least one storage medium including machine-readable instructions executable by the at least one processor and configured to cause the at least one processors to:
generate one or more signals for causing the frequency of the laser light to be varied by controllably varying a first control variable while at least some of the laser light output by a laser source is directed toward the reference medium;
using data representative of measurements of the physical property associated with the reference medium taken while the at least some laser light is being directed toward the reference medium and while the first control variable is being varied, generating data representative of a measured spectrum of the physical property as a function of the first control variable;
compare the data representative of the measured spectrum with data representative of the reference spectrum to determine whether at least a partial match exists between the measured spectrum and the reference spectrum; and
conditioned upon the at least partial match existing:
generating data representative of a set point for the measured physical property corresponding to the selected frequency marker in the reference spectrum;
generating data representative of an initial value for the first control variable corresponding to the set point for the measured physical property; and
generating one or more signals for controlling the frequency of the laser light based on the set point for the measured physical property and the initial value for the first control variable.

31. The apparatus as defined in claim 30, wherein the machine-readable instructions are configured to cause the at least one processor to generate one or more signals for causing adjustment of a second control variable prior to causing the frequency of the laser light to be varied via the first control variable.

32.-34. (canceled)

35. The apparatus as defined in claim 30, wherein comparing the measured spectrum with the reference spectrum comprises performing a thresholding operation.

36. The apparatus as defined in claim 30, wherein comparing the measured spectrum with the reference spectrum comprises comparing a center of mass associated with the measured spectrum with a center of mass associated with the reference spectrum.

37.-39. (canceled)

40. The apparatus as defined in claim 30, wherein the machine-readable instructions are configured to cause the at least one processor to generate one or more signals for controlling a temperature of the laser source.

41. (canceled)

42. The apparatus as defined in claim 30, wherein the machine-readable instructions are configured to cause the at least one processor to generate one or more signals for causing the monitoring of a pressure inside an enclosure comprising the laser source and the reference medium.

43. (canceled)

44. The apparatus as defined in claim 30, wherein the frequency marker corresponds to an atomic or molecular transition associated with the reference medium.

45. (canceled)

46. (canceled)

47. The apparatus as defined in claim 30, wherein the reference spectrum and the measured spectrum are Doppler-free spectra.

48. (canceled)

49. The apparatus as defined in claim 30, wherein the machine-readable instructions are configured to cause the at least one processor to generate one or more signals for causing adjustment of the first control variable and adjustment of a second control variable synchronously for controlling the frequency of the laser light.

50. The apparatus as defined in claim 49, wherein the first control variable comprises a length of a cavity associated with the laser source and the second variable comprises a drive current to the laser source.

51. The apparatus as defined in claim 30, wherein comparing data representative of the measured spectrum with data representative of the reference spectrum comprises comparing a derivative of the measured spectrum with a derivative of the reference spectrum.

52. The apparatus as defined in claim 30, wherein comparing data representative of the measured spectrum with data representative of the reference spectrum comprises comparing a third derivative of the measured spectrum with a third derivative of the reference spectrum.

53. The apparatus as defined in claim 30, wherein the reference medium comprises a fiber Bragg grating (FBG).

54.-60. (canceled)

61. A lidar transmitter comprising the apparatus as defined in claim 30.

62.-67. (canceled)
